(19) United States
(12) Patent Application Publication
(10) Pub. No.: US 2026/0344315 A1
(43) Pub. Date: Oct. 29, 2026

(54) METHODS FOR WET ATOMIC LAYER ETCHING OF TITANIUM NITRIDE USING OXIDATION

(71) Applicant: Tokyo Electron Limited, Tokyo (JP)

(72) Inventor: Tulashi Dahal, Austin, TX (US)

(21) Appl. No.: 19/188,707

(22) Filed: Apr. 24, 2025

(51) Int. Cl. H10P 50/28; H10P 14/60; H10P 14/692

(52) U.S. Cl. CPC H10P 50/283; H10P 14/6314; H10P 14/69394

(57) ABSTRACT

Various embodiments of methods are provided for etching titanium nitride (TiN) and other transition metal nitride materials in a wet ALE process. The methods disclosed herein use a wide variety of wet etch chemistries to: (a) oxidize a TiN surface and form a self-limiting, titanium oxide, titanium oxyhydroxide or titanium oxynitride passivation layer in a surface modification step of the wet ALE process, and (b) selectively remove the titanium oxide, titanium oxyhydroxide or titanium oxynitride passivation layer in a dissolution step of the wet ALE process. In some embodiments, a surface modification solution containing a oxidizing agent dissolved in aqueous solvent is used to form a self-limiting, titanium oxide, titanium oxyhydroxide or titanium oxynitride passivation layer, which is selectively removed in an acidic dissolution solution via reactive dissolution.

### RELATED APPLICATION

This application is related to commonly-assigned U.S. patent application Ser. No. 19/042,196, entitled “METHODS FOR WET ATOMIC LAYER ETCHING OF TITANIUM NITRIDE USING HALOGENATION,” filed Jan. 31, 2025; the disclosure of which is expressly incorporated herein, in its entirety, by reference.

### BACKGROUND

This disclosure relates to semiconductor device manufacturing, and, in particular, to the removal and etching of polycrystalline materials, such as transition metal nitrides.

During routine semiconductor fabrication, various materials may be formed on a substrate and later removed by patterned etching, chemical-mechanical polishing and other techniques. A variety of techniques are known for etching layers on a substrate, including plasma-based etching (otherwise referred to as dry etching) and liquid-based etching (otherwise referred to as wet etching). Wet etching generally involves dispensing a chemical solution over the surface of a substrate or immersing the substrate in the chemical solution. The chemical solution often contains a solvent, chemicals designed to react with materials on the substrate surface and chemicals to promote dissolution of the reaction products. As a result of exposure of the substrate surface to the etchant, material is removed from the substrate. Etchant composition and temperature may be controlled to control the etch rate, specificity and residual material on the surface of the substrate post-etch.

Thermodynamics and kinetics both play roles in etchant formulation. The desired reactions need to be both thermodynamically and kinetically favorable for a successful etch. The requirements for success become much more stringent for etching polycrystalline materials. For these materials, it is desirable that the removal rates for each individual crystallite facet and grain boundary geometry is substantially similar regardless of crystallite morphology or environment. Surface roughness plays an important role in interface quality and electrical properties of nanoscale features. When etching nanoscale polycrystalline materials, differing etch rates at grain boundaries compared to the different crystal facets leads to roughening of the surface during etching. Further, it is desirable that the material removal rate should be uniform at the macroscopic and microscopic levels and occurs at a rate that is compatible with high volume manufacturing. Macroscopic uniformity can be addressed with careful engineering, but microscopic uniformity depends on the chemistry of the etch itself.

As geometries of substrate structures continue to shrink and the types of structures evolve, the challenges of etching substrates have increased. One technique that has been utilized to address these challenges is atomic layer etching (ALE). ALE is a process that removes thin layers sequentially through one or more self-limiting reactions. For example, ALE typically refers to techniques that can etch with atomic precision, i.e., by removing material one monolayer (or a few monolayers) of material at a time. ALE processes generally rely on a chemical modification of the surface to be etched followed by a selective removal of the modified layer. Thus, ALE processes offer improved performance by decoupling the etch process into sequential steps of surface modification and removal of the modified surface. In some embodiments, an ALE process may include multiple cyclic series of layer modification and etch steps, where the modification step modifies the exposed surfaces and the etch step selectively removes the modified layer. In such processes, a series of self-limiting reactions may occur and the cycle may be repeatedly performed until a desired or specified etch amount is achieved. In other embodiments, an ALE process may use just one cycle.

A variety of ALE processes are known, including plasma ALE, thermal ALE and wet ALE techniques. Like all ALE processes, wet ALE is typically a cyclic process that uses sequential, self-limiting reactions to selectively remove material from the surface. Unlike thermal and plasma ALE, however, the reactions used in wet ALE primarily take place in the liquid phase. Compared to other ALE processes, wet ALE is often desirable since it can be conducted at (or near) room temperature and atmospheric pressure. Additionally, the self-limiting nature of the wet ALE process leads to smoothing of the surface during etching rather than the roughening commonly seen during other etch processes.

A wet ALE process typically begins with a surface modification step, which exposes a material to a first solution to create a self-limiting modified surface layer. Ideally, the modified surface layer is confined to the top monolayer of the material and acts as a passivation layer to prevent the modification reaction from progressing any further. After the modified surface layer is formed, the wet ALE process may expose the modified surface layer to a second solution to selectively dissolve the modified surface layer in a subsequent dissolution step. The dissolution step must selectively dissolve the modified surface layer without removing any of the underlying unmodified material. This selectivity can be accomplished by using a different solvent in the dissolution step than was used in the surface modification step, changing the pH, or changing the concentration of other components in the first solvent. The wet ALE cycle can be repeated until a desired or specified etch amount is achieved.

Titanium nitride (TiN) is transition metal nitride that belongs to the family of refractory compounds. This compound is widely used in medical device designs, such as cardiac pacemakers and dental implants, because of its good corrosion resistance. TiN exhibits high electron mobility and excellent thermal stability. This makes TiN an attractive material for excellent ohmic contact. It is also used as a coating material, a gate electrode in complementary metal oxide semiconductor (CMOS) and a diffusion barrier in integrated circuits. Successful integration of TiN into CM OS and memory architecture requires process uniformity across length scales. Minimizing interface resistance is also important to improve device performance. One of the ways to minimize the interface resistance is to improve the surface smoothness at the interface between a TiN layer and an adjacent overlying layer. This is uniformity on the atomic length scale. Additionally, within-feature uniformity and within-wafer uniformity play important roles in device fabrication.

Conventional methods for etching TiN include thermal and plasma ALE processes. Thermal ALE processes require high temperatures and low pressure to modify the TiN surface and remove the modified surface layer. In thermal and plasma ALE processes, the surface modifying species are reactive gas(es), ions or radicals and the volatile product that forms during removal step is toxic. The TiN etch rate achieved in such processes is low and the post-etch morphology is rougher than the as-deposited TiN surface.

Accordingly, new methods of etching and new etch chemistries are needed for etching TiN and other transition metal nitride materials formed on a substrate.

### SUMMARY

The present disclosure provides improved wet etch processes and methods for etching transition metal nitride materials. More specifically, the present disclosure provides various embodiments of wet etch processes and methods that utilize new etch chemistries for etching transition metal nitride materials, such as titanium nitride (TiN), in a wet etch process.

As described in more detail below, the embodiments disclosed herein expose a transition metal nitride surface to a first etch solution to chemically modify the transition metal nitride surface and form a modified surface layer (otherwise referred to herein as a passivation layer), which is selectively dissolved in a second etch solution to etch the transition metal nitride surface. The first etch solution includes an oxidizing agent dissolved in a first solvent. The oxidizing agent reacts with the transition metal nitride surface to oxidize the transition metal nitride surface and form a transition metal oxide, oxyhydroxide or oxynitride passivation layer, which is self-limiting and insoluble in the first solvent. The first solvent may an aqueous solvent or an organic solvent, depending on the oxidizing agent used in the first etch solution.

A wide variety of etch chemistries can be used to oxidize an exposed transition metal nitride surface (such as, e.g., titanium nitride, TiN) and form a self-limiting transition metal oxide, oxyhydroxide or oxynitride passivation layer on the underlying transition metal nitride. In one example, the embodiments disclosed herein may use an oxidizing agent to form a titanium dioxide (TiO₂), titanium oxyhydroxide (TiO(OH)₂) or titanium oxynitride (TiOₓN_{y}) passivation layer on the underlying TiN surface.

After forming a transition metal oxide, oxyhydroxide or oxynitride passivation layer, a second etch solution may be dispensed onto the surface of the substrate to selectively dissolve the transition metal oxide, oxyhydroxide or oxynitride passivation layer, thus removing the transition metal oxide, oxyhydroxide or oxynitride passivation layer from the substrate surface without etching the unmodified transition metal nitride surface underlying the transition metal oxide, oxyhydroxide or oxynitride passivation layer. Several etch chemistries can be used to selectively dissolve a titanium oxide, titanium oxyhydroxide or titanium oxynitride passivation layer without dissolving the underlying TiN surface or increasing the post-etch surface roughness of the TiN surface. In some embodiments, the second etch solution may contain an acid, or a ligand and an acid.

The embodiments disclosed herein preserve the post-etch surface roughness of the transition metal nitride layer by forming a self-limiting transition metal oxide, oxyhydroxide or oxynitride passivation layer, which is selectively removed via reactive dissolution (or ligand-assisted reactive dissolution) in the dissolution step. In some embodiments, the temperature of the first etch solution and/or the second etch solution may be selected to adjust (e.g., increase or decrease) the etch rate of the transition metal nitride layer, while preserving or improving the post-etch surface roughness of the transition metal nitride layer. For example, the etch rate of the transition metal nitride layer may be increased by elevating the temperature of the first etch solution and/or the second etch solution above room temperature. In other embodiments, the etch rate of the transition metal nitride layer may additionally or alternatively be adjusted by changing the amount of time that the transition metal nitride layer is exposed to the first etch solution and/or the second etch solution. For example, the etch rate of the transition metal nitride layer may be increased by increasing the oxidation/dissolution time.

According to one embodiment, a method is provided herein for etching a substrate having a titanium nitride (TiN) layer. In some embodiments, the method may begin by receiving a substrate having a titanium nitride (TiN) layer, where a TiN surface is exposed on a surface of the substrate, and exposing the surface of the substrate to a surface modification solution comprising an oxidizing agent dissolved in a first solvent. The oxidizing agent reacts with the TiN surface to form a titanium oxide, titanium oxyhydroxide or titanium oxynitride passivation layer, which is self-limiting and insoluble in the surface modification solution. The method further includes removing the surface modification solution from the surface of the substrate subsequent to forming the titanium oxide, titanium oxyhydroxide or titanium oxynitride passivation layer, and exposing the surface of the substrate to a dissolution solution to selectively remove the titanium oxide, titanium oxyhydroxide or titanium oxynitride passivation layer. The dissolution solution reacts with the titanium oxide, titanium oxyhydroxide or titanium oxynitride passivation layer to form soluble species, which are dissolved by the dissolution solution to expose an unmodified TiN surface underlying the titanium oxide, titanium oxyhydroxide or titanium oxynitride passivation layer. The method further includes removing the dissolution solution and the soluble species from the surface of the substrate to etch the TiN layer. In some embodiments, the steps of exposing the surface of the substrate to the surface modification solution, removing the surface modification solution, exposing the surface of the substrate to the dissolution solution, and removing the dissolution solution and the soluble species may be repeated a number of times until a predetermined amount of the TiN layer is removed from the substrate.

In some embodiments, the substrate may further include an oxide layer having an oxide surface this is exposed on the surface of the substrate. For example, the oxide layer may comprise hafnium dioxide (HfO₂), zirconium dioxide (ZrO₂) or hafnium zirconium dioxide (HfₓZr₍₁₋ₓ₎O₂). In such embodiments, the steps of exposing the surface of the substrate to the surface modification solution, removing the surface modification solution, exposing the surface of the substrate to the dissolution solution, and removing the dissolution solution and the soluble species may etch the TiN layer selective to the oxide layer.

A wide variety of oxidizing agents and solvents may be used in the surface modification solution to form the titanium oxide, titanium oxyhydroxide or titanium oxynitride passivation layer. In some embodiments, the oxidizing agent may be ammonium persulphate (APS), hydrogen peroxide (H₂O₂), nitric acid (HNO₃), pyridine N-oxide (C₅H₅NO), 4-methyl morpholine (C₅H₁₁NO) or ozone (PO₃), and the first solvent may be an aqueous solvent. In one example, the surface modification solution may comprise 1% to 20% ammonium persulfate (APS) dissolved in deionized water. When exposed to APS, a titanium dioxide (TiO₂), titanium oxyhydroxide (TiO(OH)₂) or titanium oxynitride (TiOₓN_{y}) passivation layer may be formed on the TiN surface.

In other embodiments, the oxidizing agent may be a non-peroxide oxidizer and the first solvent may be an aqueous solvent (e.g., deionized water) or an organic solvent. Examples of non-peroxide oxidizers include ammonium persulfate (APS), ferric chloride (FeCl₃), (OsO₄), ruthenium tetroxide (RuO₄), as well as various ruthenates, manganates, permanganates, periodates and metal nitrates. In yet other embodiments, the oxidizing agent may be a peroxide oxidizer and the first solvent may be an organic solvent. For example, the peroxide oxidizer may be hydrogen peroxide (H₂O₂), a symmetric organic peroxide (such as di-tert-butyl peroxide (C₈H₁₈O₂)), an asymmetric organic peroxide (such as tert-butyl peroxybenzoate (C₁₁H₁₄O₃)), a monoperoxide (such as tert-butyl hydroperoxide (C₄H10O₂)) or a peroxy acid (such as peroxyacetic acid, or peracetic acid, (C₂H₄O₃)). If an organic solvent is included within the surface modification solution, the organic solvent may be an ether, a ketone, an acetate, a halocarbon, a heterocyclic, an alcohol or another polar organic solvent or chlorocarbon solvent. Examples of organic solvents include, but are not limited to, ethyl acetate (C₄H₈O₂), acetone (C₃H₆O), methanol (CH₃OH), diethyl ether ((C₂H₅)₂O), acetonitrile (C₂H₃N), dimethyl sulfoxide (DMSO, C₂H₆OS), isopropyl alcohol (IPA, C₃H₈O), furan (C₄H₄O), dimethylformamide (C₃H₇NO), dioxane (C₄H ₈O₂) and toluene (C₆H₅CH₃).

In some embodiments, the etch rate of the TiN layer may be adjusted by adjusting the temperature of the surface modification solution to alter the solution phase kinetics of the surface modification step. In one example, the surface modification step may be performed at (or near) room temperature (e.g., approximately 20-24 °C). In another example, the temperature of the surface modification solution may be elevated above room temperature (e.g., approximately 25-100 °C) to increase the rate of oxidation and the etch rate of the TiN layer. However, the temperature of the surface modification solution may generally depend on the first solvent used in the surface modification solution. For example, the surface of the substrate may be exposed to the surface modification solution at an elevated temperature ranging between 25 °C and 100 °C when deionized water is used in the surface modification solution. Increasing the temperature of the surface modification solution increases the etch rate of the TiN layer by increasing an oxidation rate of the TiN surface and/or the thickness of the titanium oxide, titanium oxyhydroxide or titanium oxynitride passivation layer formed thereon. In some embodiments, the temperature of the surface modification solution may include the entire liquid range of the solvent used. For example, when a non-aqueous solvent is used, the temperature of the surface modification solution may range between approximately: (a) −83 °C to 77 °C for ethyl acetate, (b) −95 °C to 56 °C for acetone, (c) 19 °C to 189 °C for DMSO, etc.

In some embodiments, the dissolution solution may be an aqueous or non-aqueous solution containing: (a) an acid, or (b) an acid and a ligand. Examples of acids that may be included within the dissolution solution include, but are not limited to, sulfuric acid (H₂SO₄), hydrochloric acid (HCl) and hydrofluoric acid (HF). The acid within the dissolution solution reacts with the titanium oxide, titanium oxyhydroxide or titanium oxynitride passivation layer to form soluble species, which are selectively dissolved by the dissolution solution to expose the unmodified TiN surface underlying the titanium oxide, titanium oxyhydroxide or titanium oxynitride passivation layer. In one example embodiment, the dissolution solution may be an acidic solution comprising 0.05 mM to 5 M of sulfuric acid (H₂SO₄).

In some embodiments, the dissolution temperature may be elevated above room temperature to increase the rate of dissolution and the etch rate of the TiN layer. For example, the surface of the substrate may be exposed to the dissolution solution at an elevated temperature (ranging, e.g., between 25 °C and 100 °C for aqueous dissolution solutions) to increase the etch rate of the TiN layer by increasing a dissolution rate of the titanium oxide, titanium oxyhydroxide or titanium oxynitride passivation layer. In some embodiments, a dissolution temperature between 50 °C and 100 °C (for aqueous dissolution solutions) may provide an optimum TiN etch rate.

In some embodiments, a ligand may be added to the dissolution solution to assist in the selective dissolution of the titanium oxide, titanium oxyhydroxide or titanium oxynitride passivation layer and/or increase the dissolution rate of the titanium oxide, titanium oxyhydroxide or titanium oxynitride passivation layer. The ligand added to the dissolution solution may be a complexing agent, a chelating agent or a reducing agent. Examples of ligands that can be added to the dissolution solution include, but are not limited to, catechol, cupferron and oxalic acid. However, other ligands can also be used to assist in the selective dissolution of the titanium oxide, titanium oxyhydroxide or titanium oxynitride passivation layer. For example, carboxylic acids (such as, e.g., oxalic acid, formic acid, acetic acid, etc.), amine-containing ligands (such as, e.g., cupferron, ethylenediamine, ethylenediaminetetraacetic acid (EDTA), iminodiacetic acid, etc.), ascorbate anion-containing ligands (such as, e.g., ascorbic acid, sodium ascorbate, calcium ascorbate or potassium ascorbate, etc.) and other molecules that bind to the titanium metal surface through N, P, O, or S heteroatoms can be used as a ligand.

According to another embodiment, a method is provided herein for etching a substrate using a wet atomic layer etching (ALE) process. In some embodiments, the method may begin by receiving the substrate, the substrate having a titanium nitride (TiN) layer, wherein a TiN surface is exposed on a surface of the substrate. The method further includes selectively etching the TiN layer by performing multiple cycles of the wet ALE process, wherein each cycle comprises: (a) exposing the TiN surface to a first etch solution comprising an oxidizing agent in an aqueous solvent to form a chemically modified TiN surface layer that is self-limiting and insoluble in the first etch solution; (b) rinsing the substrate with a first purge solution to remove the first etch solution from the surface of the substrate; (c) exposing the chemically modified TiN surface layer to a second etch solution to selectively dissolve the chemically modified TiN surface layer expose an unmodified TiN surface underlying the chemically modified TiN surface layer; and (d) rinsing the substrate with a second purge solution to remove the second etch solution from the surface of the substrate and etch the TiN layer.

A wide variety of oxidizing agents may be used in the first etch solution to form the chemically modified TiN surface layer. In one embodiment, the first etch solution may include ammonium persulfate (APS) dissolved in deionized water. In some embodiments, a concentration of the APS in the first etch solution may range between 1% and 20%. When APS is used within the first etch solution, the APS may react with the TiN surface to form a titanium dioxide (TiO₂), titanium oxyhydroxide (TO(OH)₂) or titanium oxynitride (TiOₓN_{y}) passivation layer, which is self-limiting and insoluble in the non-aqueous solvent. However, other oxidizing agents may be used in the first etch solution, as discussed above.

In some embodiments, an acid may be used in the second etch solution to selectively dissolve the chemically modified TiN surface layer (such as, e.g., a titanium oxide, titanium oxyhydroxide or titanium oxynitride passivation layer). The acid may react with the chemically modified TiN surface layer to selectively dissolve the chemically modified TiN surface layer and expose the unmodified TiN surface underlying the chemically modified TiN surface layer. In some embodiments, the dissolution solution may further include a ligand. The ligand may be added to the dissolution to assist in the selective dissolution of the titanium halide or titanium oxyhalide passivation layer and/or increase the dissolution rate.

A wide variety of acids and ligands may be used in the second etch solution to selectively dissolve the chemically modified TiN surface layer without increasing the post-etch surface roughness of the TiN layer. For example, the acid may be sulfuric acid (H₂SO₄), hydrochloric acid (HCl), hydrofluoric acid (HF) or another mineral acid. Examples of ligands that may be added to the acid include, but are not limited to, oxalic acid, formic acid, acetic acid, cupferron, ethylenediamine, ethylenediaminetetraacetic acid (EDTA) , iminodiacetic acid, catechol, ascorbic acid, sodium ascorbate, calcium ascorbate and potassium ascorbate. In one example implementation, the dissolution solution may be an acidic solution comprising 0.05 mM to 5 M of sulfuric acid (H₂SO₄).

In some embodiments, the substrate may further include an oxide layer having an oxide surface that is exposed on the surface of the substrate. For example, the oxide layer may be hafnium dioxide (HfO₂), zirconium dioxide (ZrO₂) or hafnium zirconium dioxide (HfₓZr₍₁₋ₓ₎O₂). In such embodiments, the step of selectively etching the TiN layer may be selective to the oxide layer.

As noted above and described further herein, the present disclosure provides various embodiments of methods that utilize new etch chemistries for etching a transition metal nitride layer in a wet etch process. Specifically, methods and new etch chemistries are provided herein for etching titanium nitride (TiN) in a wet ALE process. Of course, the order of discussion of the different steps as described herein has been presented for the sake of clarity. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this Summary Section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 is a flowchart diagram illustrating one embodiment of a method that utilizes the techniques disclosed herein for etching a substrate having a titanium nitride (TiN) surface exposed on a surface of the substrate.

FIG. 2 illustrates one example of a cyclic wet ALE process that can be used to etch a transition metal nitride surface, such as a TiN surface, in accordance with a first embodiment of the present disclosure.

FIG. 3 is a graph depicting exemplary etch amounts (expressed in nanometers, nm) that may be achieved over time (expressed in minutes, min) when etching a TiN surface using various etch chemistries.

FIG. 4 is a graph depicting exemplary etch rates (expressed in nm/cycle) achieved as a function of ammonium persulfate (APS) concentration (expressed %) when etching a TiN surface using various concentrations of APS dissolved in deionized water (DIW) in the surface modification solution and 1 M of sulfuric acid (H₂SO₄) in the dissolution solution at 50 °C.

FIG. 5A is a graph depicting exemplary etch amounts (expressed in nm) and etch rates (expressed in nm/cycle) achieved as a function of cycle (expressed in cycle number) when etching a TiN surface using 2% APS dissolved in DIW in the surface modification solution and 1 M of sulfuric acid (H₂SO₄) in the dissolution solution at two different oxidation and dissolution temperatures (e.g., 27 °C and 50 °C).

FIG. 5B is a graph depicting exemplary etch amounts (expressed in nm) and etch rates (expressed in nm/cycle) achieved as a function of cycle (expressed in cycle number) when etching a TiN surface using 2% APS dissolved in DIW in the surface modification solution and 1 M of sulfuric acid (H₂SO₄) in the dissolution solution for two different oxidation and dissolution times (e.g., 45 and 50 seconds).

FIG. 6A is a graph depicting the X-ray photoelectron spectroscopy (XPS) spectra for the titanium (Ti) 2p peak before and after exposing the TiN surface to two different surface modification solutions (e.g., 2% APS in DIW and 2% trichloroisocyanuric acid (TCCA) in ethyl acetate (EA)).

FIG. 6B is a graph depicting the XPS spectra of the nitrogen (N) 1s peak before and after exposing the TiN surface to the two different surface modification solutions.

FIG. 6C is a graph depicting the XPS spectra of the oxygen (O) 1s peak before and after exposing the TiN surface to the two different surface modification solutions.

FIG. 7 is a graph depicting root mean square (RMS) roughness (expressed in nm) of an as-deposited TiN surface and post-etch TiN surfaces as a function of etch amount (expressed in nm) for the two different APS-DIW solutions (e.g., 2% APS in DIW and 5% APS in DIW).

FIG. 8 is a graph depicting exemplary etch amounts (expressed in nm) and etch rates (expressed in nm/cycle) achieved as a function of cycle (expressed in cycle number) when etching titanium nitride (TiN) and hafnium dioxide (HfO₂) surfaces using 2% APS dissolved in DIW in the surface modification solution and 1 M of sulfuric acid (H₂SO₄) in the dissolution solution.

FIG. 9 is a graph depicting exemplary etch rates (expressed in nm/cycle) achieved as a function of oxidation and dissolution time (expressed in seconds, s) when etching a TiN surface using 1% APS dissolved in DIW in the surface modification solution and 1 M of sulfuric acid (H₂SO₄) in the dissolution solution at different temperatures (e.g., 50 °C and 60 °C).

FIG. 10 provides scanning electron microscope (SEM) images depicting as-deposited TiN and post-etch TiN after etching the TiN surface using 1% APS dissolved in DIW in the surface modification solution and 1 M of sulfuric acid (H₂SO₄) in the dissolution solution for different oxidation and dissolution times (e.g., 30, 45 and 60 seconds).

FIG. 11 is a graph depicting root mean square (RM S) roughness (expressed in nm) of an as-deposited TiN surface and post-etch TiN surfaces as a function of etch amount (expressed in nm) for the different oxidation and dissolution times.

FIGS. 12A-12B are block diagrams illustrating an example test structure comprising a titanium nitride (TiN) layer sandwiched between two hafnium dioxide (HfO₂) layers before (FIG. 12A) and after (FIG. 12B) etching the TiN layer using 2% APS dissolved in DIW in the surface modification solution and 1 M of sulfuric acid (H₂SO₄) in the dissolution solution at 60 °C for 60 seconds.

FIGS. 13A-13B are SEM images depicting the example test structure shown in FIGS. 12A-12B before (FIG. 13A) and after (FIG. 13B) etching the TiN layer using 2% APS dissolved in DIW in the surface modification solution and 1 M of sulfuric acid (H₂SO₄) in the dissolution solution at 60 °C for 60 seconds.

FIG. 14 is a flowchart diagram illustrating one embodiment of a method that utilizes the techniques disclosed herein for etching a substrate having a TiN surface exposed on a surface of the substrate using a cyclic wet atomic layer etching (ALE) process.

FIG. 15 is a block diagram illustrating one embodiment of a processing system that can be used to etch a transition metal nitride surface, such as a TiN surface, using the wet ALE processes disclosed herein.

### DETAILED DESCRIPTION

Wet atomic layer etching (ALE) processes can be used to etch transition metals (and other materials) formed on a substrate by performing one or more cycles of the wet ALE process, where each cycle includes a surface modification step and a dissolution step. In the surface modification step, an exposed surface of the transition metal may be exposed to a surface modification solution to chemically modify the exposed surface of the transition metal and form a modified surface layer. In the dissolution step, the modified surface layer is selectively removed by exposing the modified surface layer to a dissolution solution to dissolve the modified surface layer and exposed an unmodified surface of the transition metal. Purge steps are performed between the surface modification and dissolution steps to prevent the surface modification and dissolution solutions from mixing, and the process may be repeated in a cyclic manner until a desired amount of etching is achieved. In order to achieve atomic layer etching, however, at least one of the surface modification and dissolutions steps must be self-limiting.

A variety of transition metals have been etched using wet ALE processes, including cobalt (Co), ruthenium (Ru), copper (Cu), gold (Au), platinum (Pt), Iridium (Ir), molybdenum (Mo), tungsten (W), etc. Wet ALE processes for etching such transition metals are disclosed in various commonly-assigned patents and applications, including U.S. Pat. No. 10,982,335, entitled “Wet Atomic Layer Etching Using Self-Limiting and Solubility-limited Reactions,” U.S. Pat. No. 11,802,342, entitled “Methods for Wet Atomic Layer Etching of Ruthenium,” U.S. Pat. No. 11,866,831, entitled “Methods for Wet Atomic Layer Etching of Copper,” U.S. Patent Application Publication No. 2023/0121246, entitled “Methods for Wet Atomic Layer Etching of Noble Metals,” U.S. patent application Ser. No. 18/240,142, entitled “Methods for Wet Atomic Layer Etching of Molybdenum,” U.S. patent application Ser. No. 18/619,491, entitled “Methods for Wet Atomic Layer Etching of Tungsten,” U.S. patent application Ser. No. 18/636,818, entitled “Methods for Wet Atomic Layer Etching of Molybdenum in Aqueous Solution,” and U.S. patent application Ser. No. 18/900,795, entitled “Methods for Wet Atomic Layer Etching of Tungsten Using Halogenation,” each of which is incorporated herein by reference.

Wet ALE processes have also been used to etch transition metal oxide dielectrics such as, e.g., zirconium dioxide (ZrO₂), hafnium dioxide (HfO₂) and hafnium zirconium dioxide (HfₓZr_{(1×x)}O₂) dielectrics. Commonly assigned U.S. patent application Ser. No. 18/542,181, entitled “Methods for Wet Atomic Layer Etching of Transition Metal Oxide Dielectric Materials,” discloses various wet ALE processes and methods for etching transition metal oxide dielectric materials.

In the previously disclosed wet ALE methods, oxidation or halogenation is used in the surface modification step to chemically modify an exposed surface of a transition metal layer or a transition metal oxide layer and form a self-limiting passivation layer, which is selectively removed in a subsequent dissolution step to etch the transition metal layer or transition metal oxide layer. Through extensive research and experimentation, the present inventors recognized that similar etch chemistry can be used to etch a transition metal nitride layer in a wet ALE process.

Titanium nitride (TiN) is one example of a transition metal nitride layer that is commonly used in various integrated circuits. As noted above, TiN is typically etched using a thermal ALE process or a plasma-based etch process, such as reactive ion etching (RIE). These etch processes have several disadvantages. For example, thermal ALE requires the surface modification and removal steps to be performed at high temperatures (e.g., 150-350 °C) and low pressure (e.g., about 1 Torr), which requires significant power consumption. In one example thermal ALE process, a TiN surface may be exposed to a strong gas-phase oxidant (such as ozone, O₃) at high temperature and low pressure to form a titanium oxide (TiO₂) surface layer on the TiN surface. The TiO₂ surface layer may be subsequently removed by exposing the modified surface to a gas-phase fluorinating agent (such as hydrogen fluoride, HF), which reacts with the TiO₂ surface layer to form titanium tetrafluoride (TiF₄) and water (H₂O) as reaction by-products. In the thermal ALE process described above, the volatile reaction product (TiF₄) formed during the removal step is toxic and the post-etch surface roughness is typically higher than the starting surface. RIE, on the other hand, is an anisotropic etch process that uses reactant gases to form a modified surface layer on a TiN surface and high energy ions to remove the modified surface layer from the TiN surface. This anisotropic process often leads to undercutting and damage to the underlying layers.

In contrast to conventional thermal and plasma-based etch processes, wet ALE is an isotropic process that can be achieved at (or near) room temperature and ambient pressure. As noted above, wet ALE utilizes a first etch solution (e.g., a surface modification solution) to form a conformal modified surface layer on an exposed substrate surface that can be selectively removed by a second etch solution (e.g., a dissolution solution) to preserve, or even improve, the post-etch surface morphology. The self-limiting nature of the wet ALE process can also improve the etch behavior in high aspect ratio features by eliminating depth-loading effects.

The present disclosure provides a new wet ALE process for etching a transition metal nitride layer formed on a substrate. More specifically, the present disclosure provides various embodiments of methods that utilize new etch chemistries for etching titanium nitride (TN) in a wet ALE process. As described in more detail below, the wet ALE processes and methods disclosed herein use an oxidizing agent to oxidize a TiN surface exposed on a substrate and form a self-limiting, titanium oxide, titanium oxyhydroxide or titanium oxynitride passivation layer on the underlying TiN surface in a surface modification step of the wet ALE process. The titanium oxide, titanium oxyhydroxide or titanium oxynitride passivation layer is then selectively removed in a subsequent dissolution step of the wet ALE process to etch the TiN surface at the atomic scale. In the wet ALE processes and methods disclosed herein, the temperature of the wet etch chemistry used in the surface modification/dissolution solution and/or the oxidation/dissolution time may be selected to adjust the etch rate of the TiN layer without substantially increasing the post-etch surface roughness of the TiN surface.

Unlike conventional methods for etching TiN, the methods disclosed herein utilize new etch chemistries for etching TiN in a wet ALE process that provides self-limiting behavior in the surface modification and dissolution steps. As used herein, a “self-limiting” behavior, or “self-limiting” reaction, is one in which the reaction rate goes to zero over time. In comparison to a strictly self-limiting reaction, a “quasi-self-limiting” reaction is one in which the reaction rate decreases over time but does not go to zero. In the wet ALE processes and methods disclosed herein, self-limiting behavior is provided in the surface modification step by using an oxidizing agent (such as, e.g., ammonium persulfate (APS)) dissolved in a first solvent (such as, e.g., deionized water (DIW)) to form a titanium oxide, titanium oxyhydroxide or titanium oxynitride passivation layer that is insoluble in the first solvent. In addition to self-limiting surface modification, the wet ALE processes and methods disclosed herein may provide self-limiting behavior in the dissolution step by using reactive dissolution (or ligand-assisted reactive dissolution) to selectively remove the titanium oxide, titanium oxyhydroxide or titanium oxynitride passivation layer.

The techniques disclosed herein can be performed on a wide variety of substrates having a wide variety of layers and features formed thereon. In general, the substrates utilized with the techniques disclosed herein may be any substrates for which the etching of material is desirable. For example, the substrate may be a semiconductor substrate having one or more semiconductor processing layers (all of which together may comprise the substrate) formed thereon. In one embodiment, the substrate may be a substrate that has been subject to multiple semiconductor processing steps which yield a wide variety of structures and layers, all of which are known in the substrate processing art. In one embodiment, the substrate may be a semiconductor wafer including the various structures and layers formed.

The techniques disclosed herein can be used to etch a wide variety of materials, including polycrystalline materials, single-crystalline materials and amorphous materials. In some embodiments, the techniques described herein may be used to etch a transition metal nitride material. In one exemplary embodiment, the material to be etched may be titanium nitride (TiN). Although the techniques described herein are discussed below in reference to etching TiN, it will be recognized by those skilled in the art that such an example is merely exemplary and the techniques described herein may be used to etch other transition metal nitride materials such as, for example, molybdenum nitride (MoN), tantalum nitride (TaN), chromium nitride (CrN), gallium nitride (GaN), aluminum nitride (AlN), hafnium nitride (HfN), zirconium nitride (ZrN) and iron nitride (FeₓN).

The techniques disclosed herein offer multiple advantages over other etch techniques used for etching transition metal nitrides. For example, the techniques disclosed herein provide the benefits of ALE, such as precise control of total etch amount, control of surface roughness, and improvements in wafer-scale uniformity. The techniques disclosed herein also provide various benefits of wet etching, such as the simplicity of the etch chamber, self-limiting reactions at near atmospheric temperature and pressure etching conditions, and reduced surface roughness. Unlike conventional etch processes used to etch transition metal nitrides, such as TiN, the techniques disclosed herein provide a wet ALE process that provides a self-limiting surface modification step and a selective dissolution step for etching the transition metal nitride surface. As such, the techniques described herein provide unique methods for etching TiN and other transition metal nitrides.

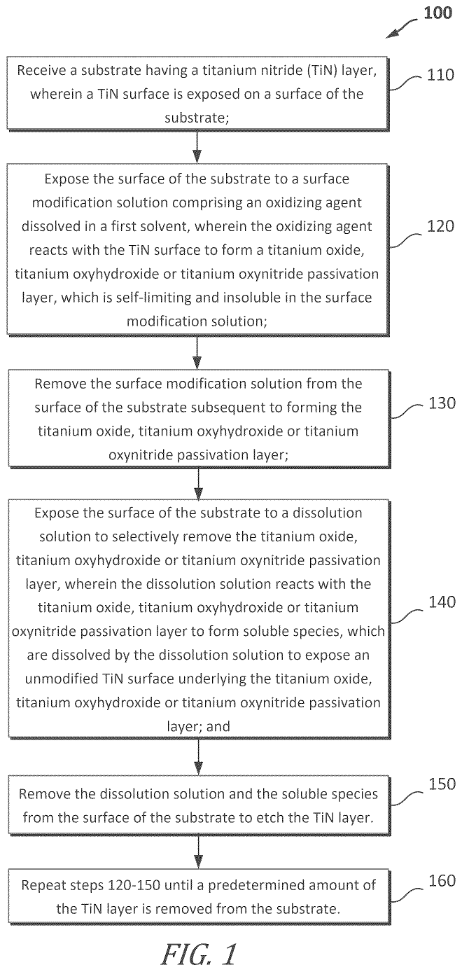

FIG. 1 illustrates one embodiment of a method 100 that can be used to etch a substrate using a wet atomic layer etching (ALE) process. More specifically, FIG. 1 illustrates an embodiment of a method 100 that can be used to etch a titanium nitride (TiN) layer formed on a substrate using a wet ALE process. It will be recognized that the embodiment of FIG. 1 is merely exemplary and additional methods may utilize the wet ALE techniques described herein. Further, additional processing steps may be added to the method shown in the FIG. 1 as the steps described are not intended to be exclusive. Moreover, the order of the steps is not limited to the order shown in the figures as different orders may occur and/or various steps may be performed in combination or at the same time.

The method 100 shown in FIG. 1 includes receiving a substrate having a titanium nitride (TiN) layer, wherein a TiN surface is exposed on a surface of the substrate (in step 110), and exposing the surface of the substrate to a surface modification solution comprising an oxidizing agent dissolved in a first solvent (in step 120). The oxidizing agent included within the surface modification solution reacts with the TiN surface to form a titanium oxide, titanium oxyhydroxide or titanium oxynitride passivation layer, which is self-limiting and insoluble in the surface modification solution. A wide variety of oxidizing agents may be included within the surface modification solution, as described in more detail below.

After forming the self-limiting titanium oxide, titanium oxyhydroxide or titanium oxynitride passivation layer, method 100 removes the surface modification solution from the surface of the substrate (in step 130), and exposes the surface of the substrate to a dissolution solution to selectively remove the titanium oxide, titanium oxyhydroxide or titanium oxynitride passivation layer (in step 140). The dissolution solution reacts with the titanium oxide, titanium oxyhydroxide or titanium oxynitride passivation layer to form soluble species, which are dissolved by the dissolution solution to expose an unmodified TiN surface underlying the titanium oxide, titanium oxyhydroxide or titanium oxynitride passivation layer. The method 100 removes the dissolution solution and the soluble species from the surface of the substrate to etch the TiN layer (in step 150). In some embodiments, the method may repeat steps 120-150 a number of times (in step 160) until a predetermined amount of the TiN layer is removed from the substrate.

The method 100 shown in FIG. 1 can be used to etch TiN (and other transition metal nitrides) in a wet ALE process by performing multiple cycles of the wet ALE process, wherein each cycle includes a surface modification step (step 120) to oxidize the TiN surface and form a titanium oxide, titanium oxyhydroxide or titanium oxynitride passivation layer, and a dissolution step (step 140) to selectively remove the titanium oxide, titanium oxyhydroxide or titanium oxynitride passivation layer without removing the unmodified TiN surface underlying the titanium oxide, titanium oxyhydroxide or titanium oxynitride passivation layer. Purge steps (steps 130 and 150) are performed between the surface modification and dissolution steps to prevent the surface modification and dissolution solutions from mixing, and the process may be repeated in a cyclic manner until a desired amount of etching is achieved. Example etch chemistries that may be used in the surface modification step (step 120), the dissolution step (step 140) and the purge steps (steps 130 and 150) are described in more detail below.

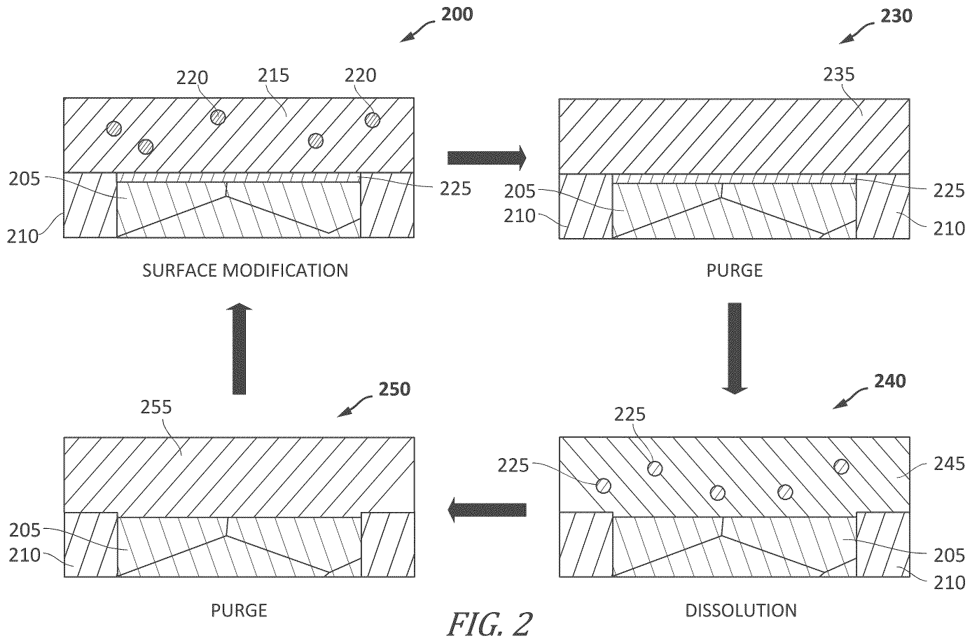

FIG. 2 illustrates one example of a wet ALE process that can be used to etch TiN (and other transition metal nitrides) in accordance with a first embodiment of the present disclosure. As described in more detail below, the wet ALE process shown in FIG. 2 is a cyclical process consisting of one or more ALE cycles, where each ALE cycle includes a surface modification step 200, a first purge step 230, a dissolution step 240 and a second purge step 250.

In the wet ALE process shown in FIG. 2, a TiN layer 205 surrounded by a dielectric material 210 is brought in contact with a surface modification solution 215 during the surface modification step 200. The surface modification solution 215 contains an oxidizing agent 220 dissolved in a first solvent (e.g., an aqueous solvent or an organic solvent). The oxidizing agent 220 reacts with an exposed surface of the TiN layer 205 to oxidize the TiN surface and form a titanium oxide, titanium oxyhydroxide or titanium oxynitride passivation layer 225, which is self-limiting and insoluble in the first solvent. The dielectric material 210 may include a wide variety of dielectric materials. In some embodiments, the dielectric material 210 may be a transition metal oxide material such as, e.g., a zirconium dioxide (ZrO₂), hafnium dioxide (HfO₂) or hafnium zirconium dioxide (HfₓZr_{(1×x)}O₂) dielectric. As described in more detail below, the surface modification solution 215 used during the surface modification step 200 may chemically modify the TiN surface and form a titanium oxide, titanium oxyhydroxide or titanium oxynitride passivation layer 225 thereon without modifying exposed surfaces of the dielectric material 210.

A wide variety of oxidizing agents 220 and solvents may be used in the surface modification solution 215. For example, the oxidizing agent 220 may be ammonium persulphate (APS), hydrogen peroxide (H₂O₂), nitric acid (HNO₃), pyridine N-oxide (C₅H₅NO), 4-methyl morpholine (C₅H₁₁NO) or ozone (O₃), and the first solvent may be an aqueous solvent such as deionized water (DIW). In one example embodiment, the surface modification solution 215 may contain 1% to 20% ammonium persulphate (APS) dissolved in deionized water (DIW). However, other oxidizing agents and solvents may also be used in the surface modification solution 215, as described in more detail below.

After forming the titanium oxide, titanium oxyhydroxide or titanium oxynitride passivation layer 225 in the surface modification step 200, the first purge step 230 is performed to remove the surface modification solution 215 from the surface of the substrate. In the first purge step 230, the substrate is rinsed with a first purge solution 235 to remove the surface modification solution 215 and excess reactants from the surface of the substrate. The first purge solution 235 should not react with the titanium oxide, titanium oxyhydroxide or titanium oxynitride passivation layer 225 formed during the surface modification step 200, or with the reactants in the surface modification solution 215. In some embodiments, the first purge solution 235 may use the same solvent (e.g., DIW) used in the surface modification solution 215. However, other solvents may also be utilized, as discussed in more detail below. In some embodiments, the first purge step 230 may be long enough to completely remove all excess reactants from the substrate surface.

After the substrate is rinsed, the dissolution step 240 is performed to selectively remove the titanium oxide, titanium oxyhydroxide or titanium oxynitride passivation layer 225 formed during the surface modification step 200. In the dissolution step 240, the substrate is exposed to a dissolution solution 245 to selectively remove or dissolve the titanium oxide, titanium oxyhydroxide or titanium oxynitride passivation layer 225 without removing the unmodified TiN layer 205 underlying titanium oxide, titanium oxyhydroxide or titanium oxynitride passivation layer 225 or the dielectric material 210 surrounding the TiN layer 205.

The dissolution solution 245 may be an aqueous or non-aqueous solution containing: (a) an acid, or (b) an acid dissolved in water. When the titanium oxide, titanium oxyhydroxide or titanium oxynitride passivation layer 225 is exposed to the dissolution solution 245, the acid within the dissolution solution 245 reacts with the titanium oxide, titanium oxyhydroxide or titanium oxynitride passivation layer 225 to form the soluble species, which are dissolved by the dissolution solution 245 to expose the unmodified TiN layer 205 underlying the titanium oxide, titanium oxyhydroxide or titanium oxynitride passivation layer 225. Examples of acids that may be included within the dissolution solution 245 include, but are not limited to, sulfuric acid (H₂SO₄), hydrochloric acid (HCl) and hydrofluoric acid (HF). In one example embodiment, the dissolution solution 245 may contain 0.05 mM to 5 M of sulfuric acid (H₂SO₄). However, other mineral acids may also be used in the dissolution solution 245.

In some embodiments, a ligand (not shown in FIG. 2) may be added to the dissolution solution 245 to assist in the selective dissolution of the titanium oxide, titanium oxyhydroxide or titanium oxynitride passivation layer 225 and/or increase the dissolution rate. A wide variety of ligands may be used in the dissolution solution 245. For example, the ligand may be a complexing agent, a chelating agent or a reducing agent. Examples of ligands that may be used in the dissolution solution 245 include catechol, cupferron and oxalic acid. Other ligands may also be utilized within the dissolution solution 245, as discussed in more detail below.

In order to selectively remove the titanium oxide, titanium oxyhydroxide or titanium oxynitride passivation layer 225, the titanium oxide, titanium oxyhydroxide or titanium oxynitride passivation layer 225 must be soluble, and the unmodified TiN layer 205 underlying the titanium oxide, titanium oxyhydroxide or titanium oxynitride passivation layer 225 must be insoluble, in the dissolution solution 245. The solubility of the titanium oxide, titanium oxyhydroxide or titanium oxynitride passivation layer 225 allows its removal through dissolution into the bulk dissolution solution 245. In some embodiments, the dissolution step 240 may continue until the titanium oxide, titanium oxyhydroxide or titanium oxynitride passivation layer 225 is dissolved.

Once the titanium oxide, titanium oxyhydroxide or titanium oxynitride passivation layer 225 is dissolved within the dissolution solution 245, the wet ALE etch cycle shown in FIG. 2 may be completed by performing a second purge step 250 to remove the dissolution solution 245 from the surface of the substrate. In the second purge step 250, the substrate is rinsed with a second purge solution 255, which may be the same or different than the first purge solution 235. In some embodiments, the second purge solution 255 may use the same solvent (e.g., DIW) used within the surface modification solution 215. However, other solvents may also be utilized, as discussed in more detail below. The second purge step 250 may generally continue until the dissolution solution 245 and/or the reactants and soluble species contained with the dissolution solution 245 are completely removed from the surface of the substrate.

Wet ALE of titanium nitride (TiN) requires the formation of a self-limiting passivation layer on the underlying unmodified TiN layer. This passivation layer must be insoluble in the first etch solution used for its formation (i.e., surface modification solution 215), but freely soluble in a second etch solution (i.e., dissolution solution 245) used for its dissolution. The self-limiting passivation layer must be removed every cycle after its formation. The second etch solution is used to selectively dissolve the passivation layer without etching the underlying unmodified TiN layer.

The wet ALE process shown in FIG. 2 may utilize a wide variety of etch chemistries to oxidize the TiN surface and form a self-limiting, titanium oxide, titanium oxyhydroxide or titanium oxynitride passivation layer in the surface modification step 200. For example, the oxidizing agent 220 used in the wet ALE process may be a peroxide oxidizer, a non-peroxide oxidizer and/or a co-oxidant.

In some embodiments, the surface modification solution 215 may contain a peroxide oxidizer dissolved in an organic solvent. Examples of peroxide oxidizers that may be included within the surface modification solution 215 include, but are not limited to, hydrogen peroxide (H₂O₂), symmetric organic peroxides (such as di-tert-butyl peroxide (C₈H₁₈O₂)), asymmetric organic peroxides (such as tert-butyl peroxybenzoate (C₁₁H₁₄O₃)), monoperoxides (such as tert-butyl hydroperoxide (C₄H₁₀O₂)), and peroxy acids (such as peroxyacetic acid, or peracetic acid, (C₂H₄O₃)). The organic solvent may be an ether, a ketone, an acetate, a halocarbon, a heterocyclic, an alcohol or another polar organic solvent or chlorocarbon solvent. Examples of organic solvents that may be used within the surface modification solution 215 include, but are not limited to, ethyl acetate (EA, C₄H₈O₂), acetone (C₃H₆O), methanol (CH₃OH), diethyl ether ((C₂H₅)₂O), acetonitrile (C₂H₃N), dimethyl sulfoxide (DMSO, C₂H₆OS), isopropyl alcohol (IPA, C₃H₈O), furan (C₄H₄O), dimethylformamide (C₃H₇NO), dioxane (C₄H₈O₂) and toluene (C₆H₅CH₃).

In one example embodiment, the surface modification solution 215 may contain hydrogen peroxide (H₂O₂) dissolved in isopropyl alcohol (IPA). Hydrogen peroxide may oxidize the TiN surface to form a titanium dioxide (TiO₂) passivation layer, which is self-limiting and insoluble in the surface modification solution 215.

In some embodiments, the wet ALE process shown in FIG. 2 may use ultra-violet (UV) photolysis to create a reactant with a very short lifetime and very high oxidation potential to perform the surface oxidation needed to form the passivation layer. During the surface modification step 200, the surface of the substrate may be exposed to UV radiation to photolyze the oxidizing agent 220 and create oxidizing radicals, which react with the exposed surface of the TiN layer 205 to oxidize the TiN surface and form a titanium oxide, titanium oxyhydroxide or titanium oxynitride passivation layer 225 (e.g., a titanium dioxide (TiO₂)). Because the lifetime of the oxidizing radicals created through UV photolysis is relatively short, the use of oxidizing radicals as an oxidizing reactant limits oxidation of the tungsten surface to provide quasi-self-limiting oxidation behavior.

A wide variety of oxidizing radicals can be formed by UV photolysis of peroxides. When hydrogen peroxide (H₂O₂) is used as the oxidizing agent 220, for example, UV photolysis of the oxidizing agent 220 creates hydroxyl radicals, which oxidize the TiN surface to form a titanium dioxide (TiO₂) passivation layer. However, other peroxides will form other types of oxidizing radicals when photolyzed. For example, UV organic peroxides will form alkoxy radicals (e.g., di-tert-butyl peroxide is photolyzed to tert-butoxy radicals) and peroxy acids will form both hydroxyl radicals and acidoxy radicals (e.g., peracetic acid will form hydroxyl and acetoxy radicals) when photolyzed. The oxidizing radicals formed from any of these peroxides can be used to oxidize the TiN surface and create a quasi-self-limiting titanium oxide, titanium oxyhydroxide or titanium oxynitride passivation layer 225.

In some embodiments, the surface modification solution 215 may contain a non-peroxide oxidizer dissolved in an aqueous solvent (such as deionized water). Examples of non-peroxide oxidizers that may be included within the surface modification solution 215 include, but are not limited to, ammonium persulphate (APS), ferric chloride (FeCl₃), nitric acid (HNO₃), pyridine N-oxide (C₅H₅NO), 4-methyl morpholine (C₅H₁₁NO) or ozone (O₃). Other examples of non-peroxide oxidizers include osmium tetroxide (OsO₄), ruthenium tetroxide (RuO₄), as well as various ruthenates, manganates, permanganates, periodates and metal nitrates. In some embodiments, an organic solvent may be used within the surface modification solution 215 in lieu of, or in addition to, the aqueous solvent. Examples of organic solvents that may be used within the surface modification solution 215 are discussed above.

In one example embodiment, the surface modification solution 215 may contain approximately 1% to 20% ammonium persulfate (APS) dissolved in deionized water. When APS is used within the surface modification solution 215, the APS may react with the TiN surface to form a titanium dioxide (TiO₂), titanium oxyhydroxide (TiO(OH)₂) or titanium oxynitride (TiOₓN_{y}) passivation layer, which is self-limiting and insoluble in the surface modification solution 215.

T the etch rate of the TiN layer 205 can be adjusted by adjusting (increasing or decreasing) the temperature of the surface modification solution 215 to alter the solution phase kinetics of the surface modification step 200. In some embodiments, the surface modification step 200 may be performed at (or near) room temperature (e.g., approximately 20-24 °C). In other embodiments, the etch rate of the TiN layer 205 may be increased by increasing the temperature of the surface modification solution 215 above room temperature. In one example, the temperature of the surface modification solution 215 may be increased to a temperature ranging, for example, between 25 °C and 100 °C to increase the etch rate of the TiN layer 205. Increasing the temperature of the surface modification solution 215 increases the etch rate of the TiN layer 205 by increasing the oxidation rate of the exposed TiN surface and/or the thickness of the titanium oxide, titanium oxyhydroxide or titanium oxynitride passivation layer 225 formed thereon. However, the temperature of the surface modification solution 215 may generally depend on the non-aqueous solvent used in the surface modification solution 215. For example, the surface of the substrate may be exposed to the surface modification solution 215 at an elevated temperature ranging between 25 °C and 100 °C when deionized is used in the surface modification solution 215. In some embodiments, the temperature of the surface modification solution 215 may include the entire liquid range of the non-aqueous solvent used. For example, the temperature of the surface modification solution 215 may range between approximately: (a)−83 °C to 77 °C for ethyl acetate, (b)−95 °C to 56 °C for acetone, (c) 19 °C to 189 °C for DM SO, etc.

After forming a self-limiting titanium oxide, titanium oxyhydroxide or titanium oxynitride passivation layer 225 using one of the oxidizing chemistries disclosed above, the wet ALE process shown in FIG. 2 may utilize a wide variety of etch chemistries to selectively remove the titanium oxide, titanium oxyhydroxide or titanium oxynitride passivation layer 225 in the dissolution step 240 without etching the unmodified TiN layer 205 underlying the passivation layer or the dielectric material 210. For example, the wet ALE process may use an acidic solution in the dissolution step 240 to selectively remove the titanium oxide, titanium oxyhydroxide or titanium oxynitride passivation layer 225 via reactive dissolution or ligand-assisted reactive dissolution.

In some embodiments, the dissolution solution 245 may be an aqueous or non-aqueous solution containing an acid such as, but not limited to, sulfuric acid (H₂SO₄), hydrochloric acid (HCl), hydrofluoric acid (HF) or another mineral acid. The acid included within the dissolution solution 245 reacts with the titanium oxide, titanium oxyhydroxide or titanium oxynitride passivation layer 225 to form soluble species, which are dissolved in the acid. In some embodiments, the temperature of the dissolution solution 245 may be elevated above room temperature to increase the etch rate of the TiN layer 205. For example, the temperature of the dissolution solution 245 may be elevated to a temperature ranging between 25 °C and 100 °C (for aqueous dissolution solutions) to increase the etch rate of the TiN layer 205 by increasing the dissolution rate of the titanium oxide, titanium oxyhydroxide or titanium oxynitride passivation layer 225.

In other embodiments, the dissolution solution 245 may be an acidic solution containing a ligand and an acid. The ligand added to the dissolution solution 245 may be a complexing agent, a chelating agent or a reducing agent. When a complexing agent or chelating agent is used, the ligand added to the dissolution solution 245 may react with and bind to the unmodified TiN layer 205 to change the surface chemistry of the unmodified TiN layer 205. In doing so, the ligand may prevent (or at least inhibit) parasitic oxidation of the unmodified TiN layer 205 by blocking the unmodified TiN surface. In other embodiments, the ligand added to the dissolution solution 245 may be a reducing agent, which inhibits parasitic oxidation of the unmodified TiN surface during the dissolution step 240. As known in the art, a “reducing agent” is a chemical species that reduces another element, molecule or compound by donating an electron to the other element, molecule or compound (i.e., an electron recipient) during an oxidation-reduction reaction. During the reaction, the reducing agent loses an electron to, or absorbs oxygen from, the electron recipient. In doing so, the reducing agent becomes oxidized and the electron recipient becomes reduced (by losing an oxygen).

In some embodiments, the wet ALE process shown in FIG. 2 may prevent (or at least inhibit) parasitic oxidation of the unmodified TiN surface and prevent continuous etching of the TiN layer 205 during the dissolution step 240 by adding a ligand to the dissolution solution 245. By forming a self-limiting titanium oxide, titanium oxyhydroxide or titanium oxynitride passivation layer 225 during the surface modification step 200 and preventing reoxidation and continuous etching of the TiN layer 205 during the dissolution step 240, the wet ALE process shown in FIG. 2 provides a post-etch surface roughness of the TiN layer 205 that is substantially equal to (or better than) an initial surface roughness of the TiN layer 205 before etching.

A wide variety of ligands may be added to the dissolution solution 245. Examples of ligands that can be added to the dissolution solution 245 include, but are not limited to, catechol (C₆H₆O₂), cupferron (C₆H₉N₃O₂) and oxalic acid (C₂H₂O₄). However, other ligands can also be used to assist in the selective dissolution of the titanium oxide, titanium oxyhydroxide or titanium oxynitride passivation layer 225 and/or prevent continuous etching of the TiN layer 205 during the dissolution step 240. For example, carboxylic acids (such as, e.g., oxalic acid (C₂H₂O₄), formic acid (HCOOH), acetic acid (CH₃COOH), etc.), amine-containing ligands (such as, e.g., cupferron (C₆H₉N₃O₂), ethylenediamine (C₂H₈N₂), ethylenediaminetetraacetic acid (EDTA, C₁₀H₁₆N₂O₈), iminodiacetic acid (C₄H₇NO₄), etc.), ascorbate anion-containing ligands (such as, e.g., ascorbic acid (C₆H₈O₆), sodium ascorbate (C₆H₇NaO₆), calcium ascorbate (C₁₂H₁₄CaO₁₂) or potassium ascorbate (KC₆H₇O₆), etc.) and other molecules that bind to the TiN surface through N, P, O, or S heteroatoms can be used in the dissolution solution 245.

In one example, the dissolution solution 245 may be an acidic solution comprising 0.05 mM to 5 M of sulfuric acid (H₂SO₄). However, other acids and ligands may be used in the dissolution solution 245 to increase the etch rate of the TiN layer 205 and prevent parasitic oxidation of the unmodified TiN surface while preserving (or improving) the post-etch surface roughness.

### Experimental Results

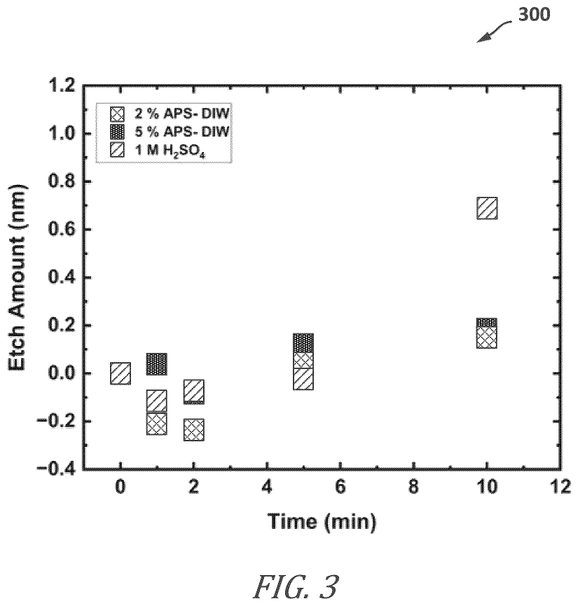

Etching experiments were conducted on 15 mm×15 mm coupons cut from a 300 mm silicon wafer with various thicknesses of TiN deposited by physical vapor deposition (PVD) on one side to investigate the wet ALE process shown in FIG. 2. The etching experiments used to etch an exposed TiN surface included multiple wet ALE cycles, where each cycle includes a dip in a surface modification solution 215 containing an oxidizing agent (e.g., APS) dissolved in aqueous solvent (e.g., deionized water, DIW), followed by a first rinse step, a dip in a dissolution solution 245 containing an acid (e.g., sulfuric acid, H₂SO₄), and a second rinse step and blow dry. Each wet ALE process was repeated for a number of ALE cycles under different process conditions to investigate the etch rate achieved by the wet ALE process shown in FIG. 2 using various oxidation and dissolution chemistries. Additional etching experiments were conducted to investigate the effect that: (a) oxidation concentration, temperature and time, and (b) dissolution temperature and time have on the TiN etch rate and post-etch surface roughness. Results of the etching experiments are shown in FIGS. 3-11.

The graph 300 shown in FIG. 3 depicts exemplary etch amounts (expressed in nanometers, nm) achieved over time (expressed in minutes, min) when etching a titanium nitride (TiN) surface using various etch chemistries. To obtain the results shown in the graph 300, a first coupon comprising a PV D-deposited TiN film was exposed to a surface modification solution 215 containing 2% APS dissolved in DIW for a variable length of time (e.g., 1-10 minutes) to oxidize the TiN surface and form a titanium oxide, titanium oxyhydroxide or titanium oxynitride passivation layer 225 on the exposed TiN surface. A second coupon comprising a PV D-deposited TiN film was exposed to a surface modification solution 215 containing 5% APS dissolved in DIW for the same amount of time. A third coupon comprising a PV D-deposited TiN film was exposed to a dissolution solution 245 containing 1M of sulfuric acid (H₂SO₄) for a variable length of time (e.g., 0-10 minutes) to investigate the background etch of TiN in the acidic dissolution solution. The temperature of the surface modification and dissolution solutions was elevated above room temperature (e.g., to 50 °C). After soaking the coupons in the surface modification and dissolution solutions for X amount of time and performing rinse and blow dry steps, 4-point probe (4pp) resistivity measurements were obtained to measure the etch amount achieved in the two solutions over time.

As shown in the graph 300, the thickness of the TiN film initially increases with soak time up to about 2 minutes in the 2% and 5% APS-DIW surface modification solutions, an indication of the formation of a surface product (e.g., a titanium dioxide (TiO₂), titanium oxyhydroxide (TiO(OH)₂) or titanium oxynitride (TiOₓN_{y}) passivation layer) that is different than the starting surface. However, additional oxidation beyond 2 minutes begins to remove material from the TiN surface. This shows that the surface modification step 200 is self-limiting only up to a certain point, after which the self-limiting behavior breaks down with longer soak times. The graph 300 further shows that, while the TiN thickness does not change during the first 5 minutes when dipped in 1M of H₂SO₄, TiN eventually reacts with H₂SO₄ to form an acid-soluble titanium species. This accounts for the continuous etch seen in longer soak times greater than 5 minutes. Accordingly, the graph 300 shown in FIG. 3 indicates that the surface modification and dissolution steps may be self-limiting during shorter soak times (e.g., up to 5 minutes).

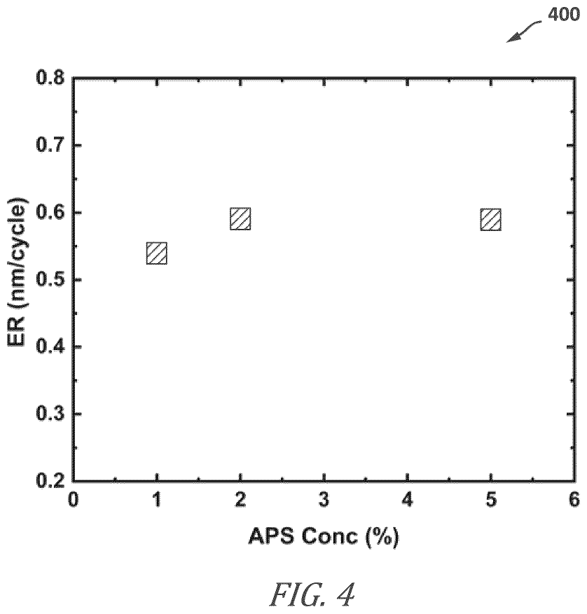

An additional etch experiment was performed to investigate the effect of oxidation concentration on the TiN etch rate. The graph 400 shown in FIG. 4 depicts exemplary etch rates (expressed in nm/cycle) achieved as a function of ammonium persulfate (APS) concentration when using various concentrations (e.g., 1%, 2% and 5%) of APS dissolved in deionized water (DIW) to oxidize the TiN surface. The etch recipe used to obtain the results shown in the graph 400 included multiple ALE cycles, where each cycle includes: (a) a 1 minute dip in X% APS in DIW solution at 50 °C, (b) a DIW/IPA rinse, (c) a 1 minute dip in 1M of H₂SO₄ solution at 50 °C, and (d) an IPA rinse and blow dry.

As shown in the graph 400, the etch rate achieved in the different APS-DIW solutions is relatively constant (~0.59 nm/cycle) with APS concentrations between 2% to 5%, indicating that the TiN removal is self-limiting and independent of the APS concentration used in the surface modification solution 215 (between 2% to 5% APS). Although not shown in the graph 400, an APS concentration of approximately 2% to 20% APS may be used in the surface modification step without comprising post-etch morphology or selectivity to certain transition metal oxide dielectrics, such as hafnium dioxide (HfO₂). A slightly lower TiN etch rate of ~0.54 nm/cycle was achieved in 1% APS-DIW solution. This may be due to an incomplete saturation of the TiN surface.

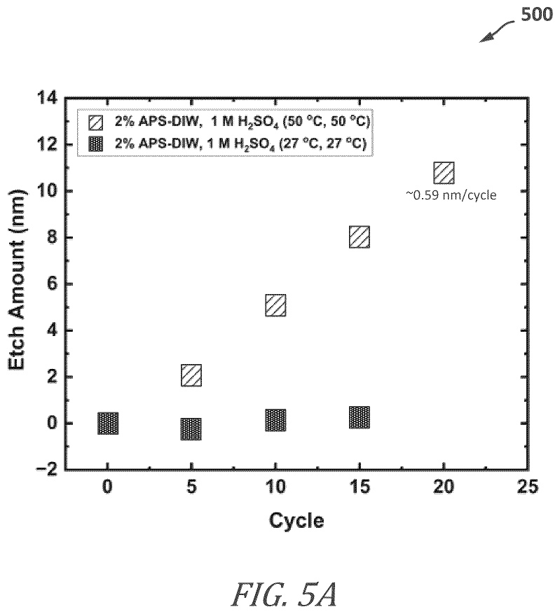

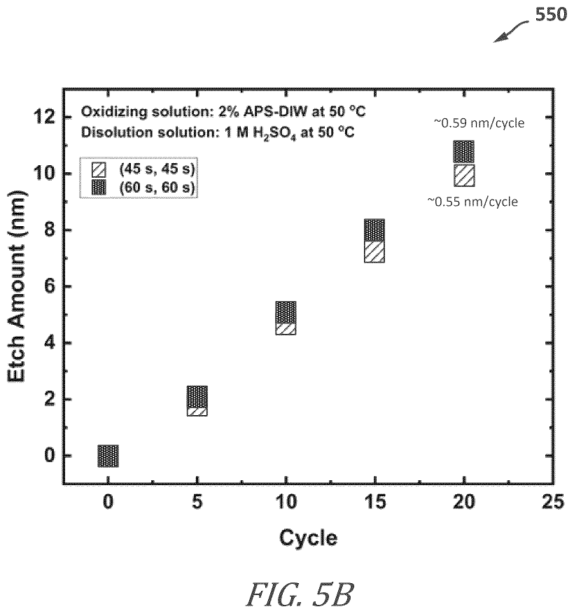

An additional experiment was carried out to study the effect of solution phase kinetics on TiN etch rate by varying oxidation/dissolution temperature. The graph 500 shown in FIG. 5A depicts exemplary etch amounts (expressed in nm) and etch rates (expressed in nm/cycle) achieved as a function of cycle (expressed in cycle number) when etching a TiN surface using 2% APS dissolved in DIW in the surface modification solution 215 and 1 M of sulfuric acid (H₂SO₄) in the dissolution solution 245 at two different temperatures (e.g., 27 °C and 50 °C). The etch recipe used to obtain the results shown in the graph 500 included multiple ALE cycles, where each cycle includes: (a) a 1 minute dip in 2% APS in DIW solution at X °C, (b) a DIW/IPA rinse, (c) a 1 minute dip in 1M of H₂SO₄ solution at X °C, and (d) an IPA rinse and blow dry. As shown in the graph 500, no change in TiN thickness was observed in the room temperature (e.g., 27 °C) oxidation/dissolution process. However, more than 10 nm of TiN was removed in 20 cycles (~0.59 nm/cycle) by elevating the oxidation/dissolution temperature to 50 °C, an indication that solution phase kinetics drives surface oxidation and selective removal of modified TiN layer.

An additional experiment was carried out to study the effect of oxidation/dissolution time on TiN etch. The graph 550 shown in FIG. 5B depicts exemplary etch amounts (expressed in nm) and etch rates (expressed in nm/cycle) achieved as a function of cycle (expressed in cycle number) when etching a TiN surface using 2% APS dissolved in DIW in the surface modification solution 215 and 1 M of sulfuric acid (H₂SO₄) in the dissolution solution 245 for different oxidation and dissolution times (e.g., 45 and 50 seconds). The etch recipe used to obtain the results shown in the graph 550 included multiple ALE cycles, where each cycle includes: (a) an X seconds (e.g., 45 and 50 seconds) dip in 2% APS in DIW solution at 50 °C, (b) a DIW/IPA rinse, (c) an X seconds (e.g., 45 and 50 seconds) dip in 1M of H₂SO₄ solution at 50 °C, and (d) an IPA rinse and blow dry. As shown in the graph 550, the TiN etch rate (ER ~0.55 nm/cycle) achieved after TiN surface modification and dissolution at 45 seconds in 2% APS-DIW and 1 M H₂SO₄ solution at 50 °C, respectively, is slightly lower than the TiN etch rate (ER ~0.59 nm/cycle) achieved after exposing the coupon for 60 s in the same surface modification and dissolution solutions. An insignificant variation in the TiN etch rate for different oxidation/dissolution times suggests that an existence of ALE window is possible.

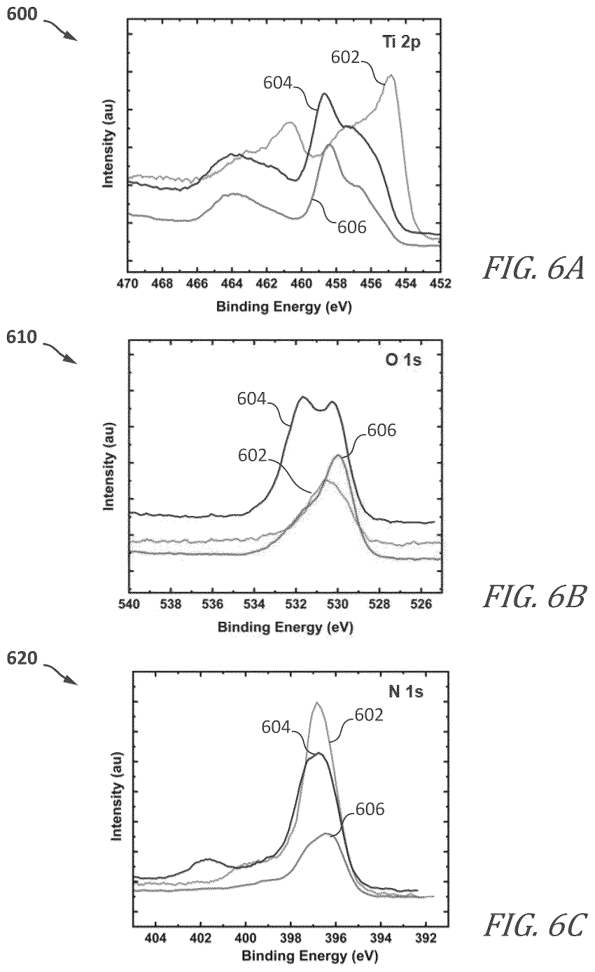

X-ray photoelectron spectroscopy (XPS) analysis was carried out to better understand the surface chemistry of TiN before and after the surface modification step 200. For the reference measurement, the as-deposited TiN surface was cleaned using an argon (Ar) beam at 1 kV to remove any contamination from the surface. Additional TiN coupons were dipped in two different surface modification solutions (e.g., 2% APS in DIW and 2% trichloroisocyanuric acid (TCCA) in ethyl acetate (EA)) for 1 minute to oxidize the TiN surface. After rinsing and blow drying the oxidized coupons, XPS analysis was performed to investigate the surface chemistry of the TiN surface on the reference coupon and the oxidized coupons. Results of the XPS analysis are shown in FIGS. 6A-6C.

The graph 600 shown in FIG. 6A depicts the XPS spectra for the titanium (Ti) 2p peak before (line 602) and after exposing the TiN surface to the two different surface modification solutions. It is evident from the graph 600 that Ti³⁺ is the dominant oxidation state in the TiN reference coupon (line 602). The existence of a higher binding energy shoulder in the TiN reference coupon also indicates the presence of an oxidized surface layer, such as titanium oxynitride. The Ti 2p peak shifts towards higher binding energy after exposing the TiN coupon to the 2% APS-DIW solution (line 604). The sharp Ti 2p peak around 458.7 eV shows surface oxidation shifts the Ti binding energy to a higher Ti⁴⁺ species, likely titanium (TiO₂). The existence of a lower binding energy peak around 457.4 eV for the TiN coupon exposed to the 2% APS-DIW solution indicates the presence of incompletely oxidized surface species. In comparison, the TiN coupon exposed to the 2% TCCA-EA solution (line 606) exhibits a sharp, but less intense Ti 2p peak around 458.6 eV, indicating that surface chlorination also shifts the Ti binding energy to a higher Ti4+species. However, the surface passivation achieved using TCCA (likely, TiOₓ(OH)₍₄₋₂ₓ₎ given the reactivity of titanium halide compounds towards atmospheric moisture) is different than the surface passivation achieved using APS (e.g., TiO₂).

The graph 610 shown in FIG. 6B depicts the XPS spectra of the oxygen (O) 1s peak before (line 602) and after exposing the TiN surface to the two different surface modification solutions. The TiN coupon dipped in the 2% APS-DIW solution (line 604) shows a splitting of the O 1s spectra and significantly increased O 1s intensity. The observed increased oxygen intensity further testifies that the APS-DIW solution changes the TiN surface to a titanium dioxide (TiO₂) surface, consistent with Ti 2p observation. The O 1s peak at the higher binding energy (~531.7 eV) is consistent with the presence of a titanium oxynitride (Ti—O—N), a titanium hydroxide (Ti—OH) or surface hydrates bond, whereas the O 1s peak at the lower binding energy (~530.2 eV) indicates the presence of titanium dioxide (TiO₂). The TiN coupon dipped in the 2% TCCA-EA solution (line 606) shows an O 1s peak at around 529.9 eV, an indication of presence of TiO₂ on the surface.

The graph 620 shown in FIG. 6C depicts the XPS spectra of the nitrogen (N) 1s peak before (line 602) and after exposing the TiN surface to the two different surface modification solutions. The N 1s peak shows that N signal decreases after exposing the TiN surface to the 2% APS-DIW solution (line 604) and significantly decreases after exposing the TiN surface to the 2% TCCA-EA solutions (line 606). This is consistent with removal of nitrogen from the surface layer. However, the N 1s signal is stronger in the TiN coupon after soaking in the 2% APS-DIW solution compared to the N 1s signal coming from TiN surface that was dipped in the 2% TCCA-EA solution, indicating greater amounts of nitrogen are removed in the 2% TCCA-EA solution. The presence of a satellite peak at around 399.1 eV and a broadened N peak at around 402 eV for the TiN coupon after soaking in the 2% APS-DIW solution indicates the presence of a titanium oxynitride (Ti—O—N) species.

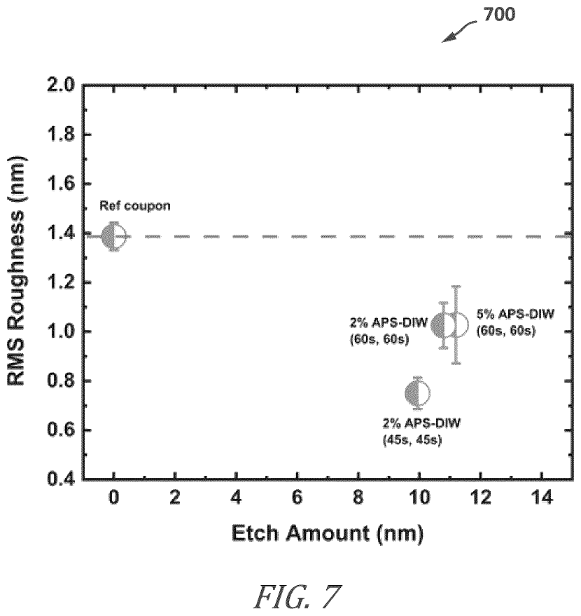

An additional etch experiment was performed to investigate the effect of oxidation concentration and time on the post-etch surface roughness. The graph 700 shown in FIG. 7 depicts the root mean square (RMS) roughness (expressed in nm) of an as-deposited TiN surface and post-etch TiN surfaces as a function of etch amount (expressed in nm) for the two different APS-DIW solutions (e.g., 2% APS in DIW and 5% APS in DIW). The etch recipe used to obtain the results shown in the graph 700 included multiple ALE cycles, where each cycle includes: (a) an X second (e.g., 45 or 60 second) dip in 2% or 5% APS-DIW solution at 50 °C, (b) a DIW/IPA rinse, (c) a 1 minute dip in 1M of H₂SO₄ solution at 50 °C, and (d) an IPA rinse and blow dry.

As shown in the graph 700, the post-etch morphology of the TiN coupon is preserved irrespective of the APS concentration and oxidation/dissolution conditions under study. In fact, the graph 700 shows that the surface roughness of the TiN coupon improves after etching with the oxidizing etch chemistry. The improved post-etch morphology is attributed to the formation of a conformal titanium dioxide (TiO₂) surface product that can be selectively removed via reactive dissolution in the sulfuric acid solution. The graph 700 shows that, when exposed to the oxidizing solution for 60 seconds, the RMS roughness (~(1.03±0.09) nm) of the post-etch TiN coupon using 2% APS-DIW solution and the RM S roughness (~(1.03±0.16) nm) of the post-etch TiN coupon using 5% APS-DIW solution are much lower than the RMS roughness (~(1.39±0.06) nm) of the as-deposited TiN reference coupon. The graph 700 further shows that the RMS roughness (~(0.75±0.06) nm) in the post-etch TiN coupon using 2% APS-DIW solution for 45 seconds is much lower compared to the RM S roughness of ~(1.03±0.09) nm of the post-etch TiN using same oxidizing solution for 60 seconds. This indicates that lower oxidizing times may be preferable when post-etch surface roughness and interface resistance are of concern. However, the graph 700 shows that slightly higher etch amounts/rates are achieved using higher APS concentrations (e.g., 5% vs 2% APS). Thus, higher APS concentrations may be used to increase the TiN etch rate when throughput is a concern.

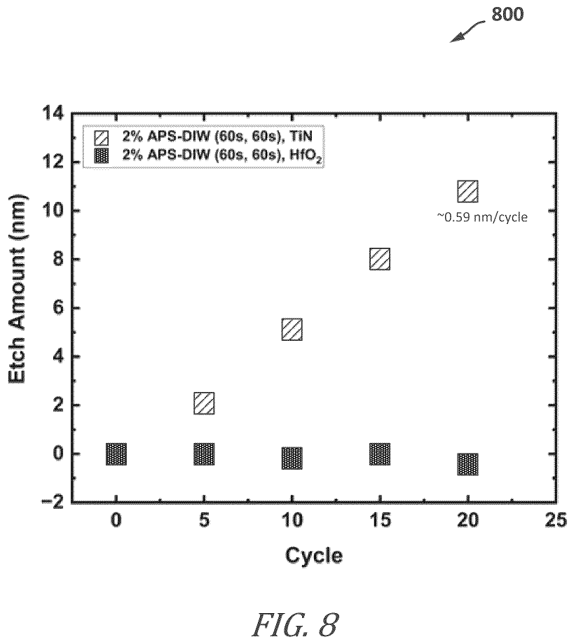

Additional etch experiments were performed to investigate the etch selectivity between TiN and hafnium dioxide (HfO₂). The graph 800 shown in FIG. 8 shows the etch amounts (expressed in nm) and etch rate (expressed in nm/cycle) achieved when etching TiN and HfO₂ using 2% APS dissolved in DIW in the surface modification solution and 1 M of sulfuric acid (H₂SO₄) in the dissolution solution. The etch recipe used to obtain the results shown in the graph 800 included multiple ALE cycles, where each cycle includes: (a) a 1 minute dip in 2% APS in DIW solution at 50 °C, (b) a DIW/IPA rinse, (c) a 1 minute dip in 1M of H₂SO₄ solution at 50 °C, and (d) an IPA rinse and blow dry.

As shown in the graph 800, more than 10 nm of TiN is removed off the TiN surface after 20 cycles of the wet ALE process, while the thickness of HfO₂ remains nearly the same. Specifically, the TiN etch rate is ~0.59 nm/cycle after oxidation and dissolution at 50 °C. The graph 700 shows that APS changes the surface chemistry of TiN to form a surface product that is soluble in acidic medium. However, the graph 700 further shows that the same etch chemistry cannot be used to remove HfO₂. This may be due, at least in part, to the difficulty in changing the surface chemistry of HfO₂ and/or the difficulty of dissolving HfO₂ in low concentration H₂SO₄ at or near room temperature. This offers a great etch selectivity between TiN and HfO₂.

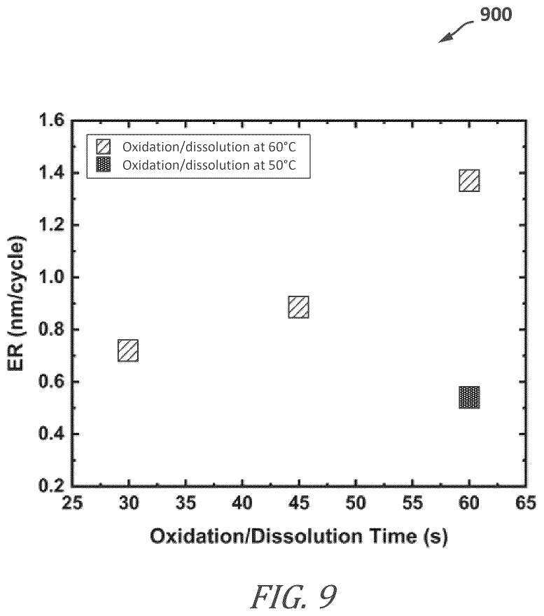

To understand the effect of low APS concentrations in TiN etch at slightly higher temperatures for different oxidation/dissolution time, the TiN surface was exposed to 1% APS-DIW solution at 60 °C followed by the selective removal of modified layer in 1 M H₂SO₄ at 60 °C. The graph 900 shown in FIG. 9 depicts the TiN etch rates (expressed in nm/cycle) achieved as a function of oxidation and dissolution time (expressed in seconds, s) when etching a TiN surface using 1% APS dissolved in DIW in the surface modification solution and 1 M of sulfuric acid (H₂SO₄) in the dissolution solution at different temperatures (e.g., 50 °C and 60 °C). The etch recipe used to obtain the results shown in the graph 900 included multiple ALE cycles, where each cycle includes: (a) an X second (e.g., 30, 45 or 60 second) dip in 1% APS in DIW solution at Y °C (e.g., 50°C or 60°C), (b) a DIW/IPA rinse, (c) an X second (e.g., 30, 45 or 60 second) dip in IM of H₂SO₄ solution at Y °C (e.g., 50 °C or 60 °C), and (d) an IPA rinse and blow dry.

The graph 900 shows that, for the same oxidation/dissolution time (60 seconds), a slight increase in the oxidation/dissolution temperature (e.g., 60 °C vs 50 °C) results in a much higher TiN etch rate. Specifically, the graph 900 shows that the TiN etch rate (~1.37 nm/cycle) at 60°C oxidation/dissolution temperature for a 1 minute soak in 1% APS-DIW and followed by the selective removal of the modified TiN layer in 1 M H₂SO₄ solution at 60 °C is about 2.5 times higher than the TiN etch rate (~0.54 nm cycle) achieved with the same oxidizing solution at 50 °C oxidation/dissolution temperature. The significant enhancement in the TiN etch rate at higher temperature suggests that TiN surface modification and its removal are greatly controlled by solution phase kinetics.

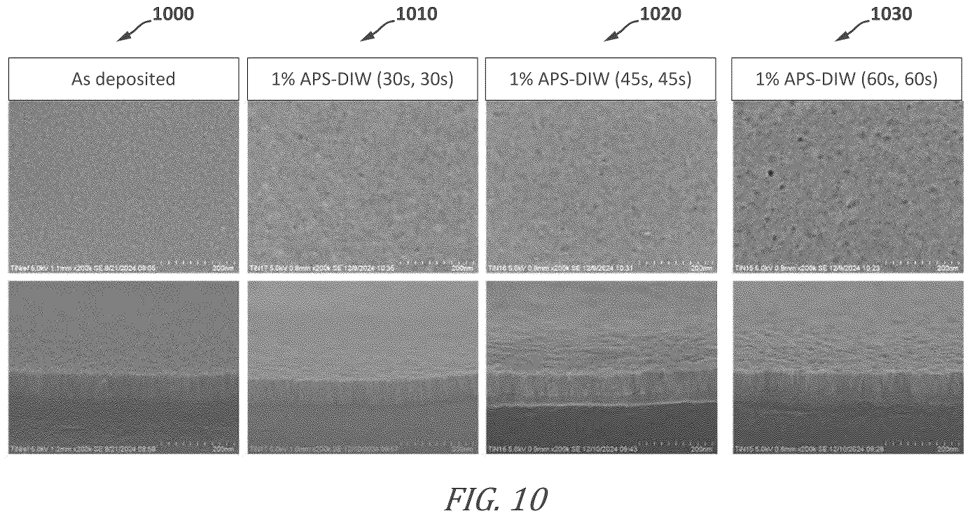

The post-etch surface morphology was characterized using a scanning electron microscope (SEM) . FIG. 10 provides top and tilt views of SEM images of an as-deposited TiN surface (1000) and various post-etch TiN surfaces (1010, 1020 and 1030) after etching the TiN surfaces using 1% APS dissolved in DIW in the surface modification solution and 1 M of sulfuric acid (H₂SO₄) in the dissolution solution at 60 °C for different oxidation and dissolution times (e.g., 30, 45 and 60 seconds). The top views of the post-etch SEM images show improved surface morphology in the post-etch TiN coupon with the shortest oxidation/dissolution time (e.g., 30 seconds). However, pitting of the TiN surface occurs with longer oxidation/dissolution times, possibly due to the difference in reaction kinetics between grain boundary and the grain surface.

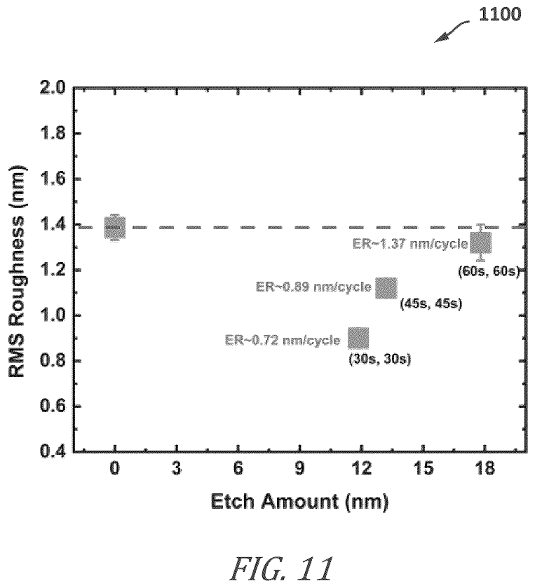

The graph 1100 shown in FIG. 11 depicts the root mean square (RMS) roughness (expressed in nm) of the as-deposited TiN surface (1000) and the post-etch TiN surfaces (1010, 1020 and 1030) as a function of etch amount (expressed in nm) for the different oxidation and dissolution times (30, 45 and 60 seconds). As shown in the graph 1100, the measured RMS roughness in all post-etch TiN coupons is less than, or nearly the same as, the as-deposited reference coupon. The graph 1100 further shows the increase in etch rate (ER) achieved with increasing the oxidation/dissolution time. For example, the graph 1100 shows a TiN etch rate of: (a) ~0.54 nm cycle is achieved with 30 seconds of oxidation/dissolution, (b) ~0.89 nm cycle is achieved with 45 seconds of oxidation/dissolution, and (c) ~1.37 nm cycle is achieved with 60 seconds of oxidation/dissolution, all without increasing the post-etch surface roughness of the TiN coupon.

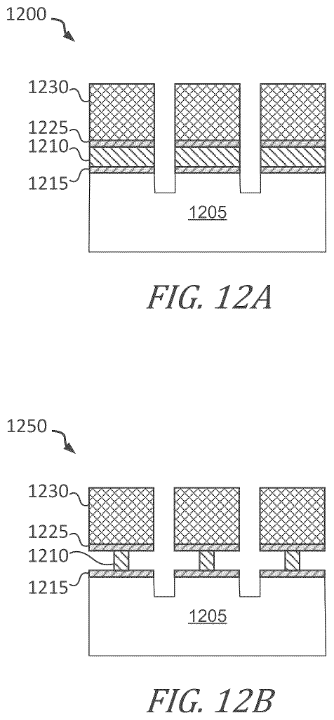

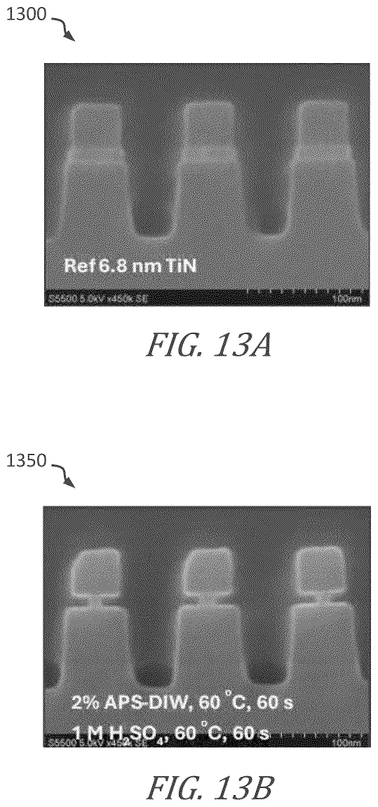

Additional experiments were performed to investigate etching of an example test structure using the wet ALE methods and new etch chemistries disclosed herein. FIG. 12A depicts an example test structure 1200 comprising a titanium nitride (TiN) layer 1210 sandwiched between a second hafnium dioxide (HfO₂) layer 1225 and a first HfO₂ layer 1215, which is formed on a substrate 1205. An amorphous silicon (a-Si) layer 1230 is formed above and in contact with the second HfO₂ layer 1225. In the example test structure 1200, the TiN layer 1210 was approximately 6.8 nm thick, the first and second HfO₂ layers 1215 and 1225 were approximately 2 nm thick, and the a-Si layer 1230 was approximately 40 nm thick. After forming the various layers of the test structure 1200, the test structure was patterned and etched as shown in FIG. 12A to expose side surfaces of the layers 1210, 1215, 1225 and 1230. A SEM image 1300 of the example test structure 1200 is shown in FIG. 13A.

The example test structure 1200 shown in FIGS. 12A and 13A was etched using the etch chemistries and methods disclosed herein to investigate the effectiveness of an aqueous TiN etch chemistry as described herein when etching the TiN layer 1210 from a nano-confined region selective to the HfO₂ layers 1215 and 1225. During the experiment, the test structure 1200 was exposed a surface modification solution containing 2% APS dissolved in DIW, followed by dissolution in 1 M of H₂SO₄. The oxidation and the dissolution solution were both performed at 60 °C for 60 seconds. Purge steps were performed between the oxidation and dissolution steps, as discussed above. The post-etch results are shown in FIG. 12B and the SEM image 1350 shown in FIG. 13B. As shown in FIGS. 12B and 13B, the post-etch test structure 1250 demonstrates lateral etching of the TiN layer 1210 with little to no etching of the HfO₂ layers 1215 and 1225 adjacent to the TiN layer 1210 or the overlying a-Si layer 1230. It is evident from the SEM of FIG. 13B that the aqueous etch chemistry is effective on removing TiN selective to HfO₂, an indication that aqueous etch chemistry can remove the TiN from nano-confined regions. Thus, the post-etch results show that the aqueous TiN etch chemistry disclosed herein offers excellent selectivity with HfO₂ and provides a way to successfully remove TiN from relatively small (e.g., less than 10 nm) nano-confined regions.

As shown in the etching experiments above, the surface modification of TiN is self-limiting in aqueous oxidizing solutions (such as, e.g., APS-DIW) and acidic dissolutions up until a certain point (such as, e.g., 5 minutes). Self-limiting behavior during the surface modification step is attributed to the formation of a conformal titanium oxide passivation layer (e.g., a titanium dioxide (TiO₂) passivation layer), which is insoluble in the aqueous solvent used in the surface modification solution. The modified TiN surface layer is subsequently removed via reactive dissolution in acidic solution. The etching experiments provided herein further show that the TiN etch rate (ER) is independent of the APS concentrations (e.g., 2-5% APS) under study, but can be tuned by changing the oxidation/dissolution temperature and/or time. As shown above, the post etch surface morphology is preserved (and often improved) irrespective of APS concentration. In fact, low oxidizer concentration and shorter oxidation/dissolution temperatures and times result in a substantially smoother surface morphology in the post-etch TiN coupon. The preserved surface smoothness in the post-etch TiN coupon can be attributed to the formation of the conformal titanium oxide (e.g., a titanium dioxide (TiO₂)) passivation layer that prevents continuous TiN etch. The XPS spectra shows that exposing TiN coupon to the APS-DIW solution changes the Ti oxidation state from Ti3+to Ti⁴⁺ (likely, TiO₂), while splitting of the O 1s spectra (in FIG. 6B) indicates presence of additional surface species different than TiO₂ (such as a titanium oxynitride (Ti—O—N), a titanium hydroxide (Ti—OH) or surface hydrates bond). The etch chemistry used herein for etching TiN also provides excellent selectivity between TiN and surrounding dielectric materials, such as HfO₂, and has been shown to remove TiN selective to HfO₂ from a nano-confined region, thus mitigating loading depth effects.

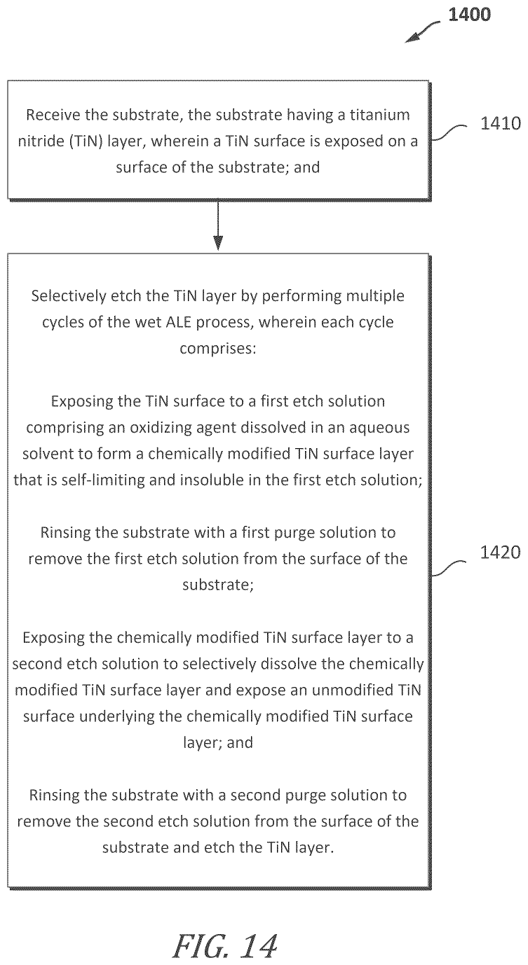

FIG. 14 illustrates another embodiment of a method 1400 that can be used for etching a substrate using a wet ALE process. M ore specifically, FIG. 14 illustrates a method 1400 that can be used to etch a substrate having a titanium nitride (TiN) layer using a wet ALE process, which utilizes oxidation to modify a TiN surface and form a chemically modified TiN surface layer. It will be recognized that the embodiment of FIG. 14 is merely exemplary and additional methods may utilize the wet ALE techniques described herein. Further, additional processing steps may be added to the method shown in the FIG. 14 as the steps described are not intended to be exclusive. Moreover, the order of the steps is not limited to the order shown in the figures as different orders may occur and/or various steps may be performed in combination or at the same time.

The method 1400 shown in FIG. 14 begins by receiving the substrate, the substrate having a titanium nitride (TiN) layer, wherein a TiN surface is exposed on a surface of the substrate (in step 1410). Then, in step 1420, the method 1400 includes selectively etching the TiN layer by performing multiple cycles of the wet ALE process, wherein each cycle comprises: (a) exposing the TiN surface to a first etch solution comprising an oxidizing agent dissolved in an aqueous solvent to form a chemically modified TiN surface layer that is self-limiting and insoluble in the first etch solution; (b) rinsing the substrate with a first purge solution to remove the first etch solution from the surface of the substrate; (c) exposing the chemically modified TiN surface layer to a second etch solution to selectively dissolve the chemically modified TiN surface layer and expose an unmodified TiN surface underlying the chemically modified TiN surface layer; and (d) rinsing the substrate with a second purge solution to remove the second etch solution from the surface of the substrate and etch the TiN layer.

In the method 1400, the oxidizing agent reacts with the TiN surface to form a titanium oxide, titanium oxyhydroxide or titanium oxynitride passivation layer, which is self-limiting and insoluble in the first etch solution. In some embodiments, a temperature of the first etch solution and the second etch solution and/or a time duration during which the substrate is exposed to the first etch solution and the second etch solution may be selected to adjust an etch rate of the TiN layer without substantially increasing a post-etch surface roughness of the TiN layer compared to an initial surface roughness of the TiN layer before etching. In some embodiments of the method 1400, the substrate may further include an oxide layer having an oxide surface that is exposed on the surface of the substrate. For example, the oxide layer may be hafnium dioxide (HfO₂), zirconium dioxide (ZrO₂) or hafnium zirconium dioxide (HfₓZr₍₁₋ₓ₎O₂). In such embodiments, the step of selectively etching the TiN layer may be selective to the oxide layer.

A wide variety of oxidizing agents and solvents may be utilized in the first etch solution, as described above. In some embodiments, the oxidizing agent may be ammonium persulfate (APS) and the aqueous solvent may be deionized water (DIW). In some embodiments, the APS concentration in the first etch solution may range between 1% and 20%. In the example experiments disclose herein, an APS concentration between 2% and 5% was used to etch the TiN surface without increasing the post-etch surface roughness of the TiN layer. In one example embodiment, the first etch solution may comprise 1-2% APS dissolved in DIW. However, the oxidizing agent used to chemically modify the TiN surface in method 1400 is not limited to APS and may include other non-peroxide oxidizers, peroxide oxidizers and/or co-oxidants, as described further above.

In some embodiments, the second etch solution may comprise an acid. The titanium oxide, titanium oxyhydroxide or titanium oxynitride passivation layer may selectively dissolved by the acid included within the second etch solution to expose the unmodified TiN surface underlying the titanium oxide, titanium oxyhydroxide or titanium oxynitride passivation layer. In some embodiments, the second etch solution may further comprise a ligand to assist in the selective dissolution of the titanium oxide, titanium oxyhydroxide or titanium oxynitride passivation layer and/or increase the dissolution rate.

A wide variety of acids and ligands may be utilized in the second etch solution, as described above. For example, the acid may be sulfuric acid (H₂SO₄), hydrochloric acid (HCl), hydrofluoric acid (HF) or another mineral acid, and the ligand may be oxalic acid, formic acid, acetic acid, cupferron, ethylenediamine, ethylenediaminetetraacetic acid (EDTA) , iminodiacetic acid, catechol, ascorbic acid, sodium ascorbate, calcium ascorbate or potassium ascorbate. In one example embodiment, the second etch solution may include 0.05 mM to 5 M of sulfuric acid (H₂SO₄).

The methods and wet ALE processes described above and shown in FIGS. 1, 2 and 14 for etching TiN can be accomplished using a variety of techniques. For example, the TiN wet ALE processes disclosed above may be performed by dipping the TiN sample in beakers of each etch solution. In this case, purging can be accomplished by either rinsing or dipping the sample in an appropriate solvent bath. The TiN wet ALE processes can also be accomplished on a spinner. For example, the TiN sample may be rotated while the etchant solutions are dispensed from a nozzle positioned above the sample. The rotational motion of the sample distributes the solution over the surface. After the set exposure time, the nozzle begins dispensing the next solution in the etch recipe. This process continues through the whole etch cycle and repeats for as many cycles as necessary to remove the desired amount of TiN. For high volume manufacturing, dispensing of etch solutions and rinses can be executed using conventional tools, such as wet etching tools and rinse tools.

Example process conditions (e.g., etch chemistry, temperature, processing time, etc.) are provided herein for etching transition metal nitride materials, and more specifically, for etching titanium nitride (TiN) using the methods and wet ALE processes described above and shown in FIGS. 1, 2 and 14. It will be recognized by those skilled in the art, however, that the methods and wet ALE processes disclosed herein are not strictly limited to the example process conditions described herein and may be performed using a wide variety of process conditions depending on the material being etched.

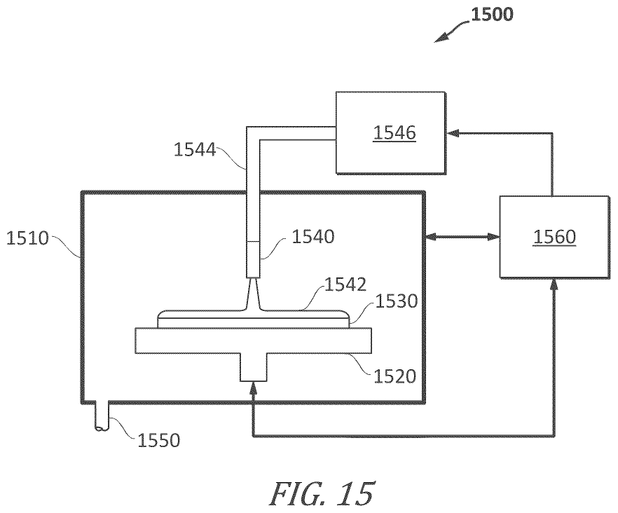

FIG. 15 illustrates one embodiment of a processing system 1500 that can etch a transition metal nitride surface, such as a TiN surface, on a surface of a substrate 1530 using the wet ALE processes disclosed herein. As shown in FIG. 15, the processing system 1500 includes a process chamber 1510, which in some embodiments, may be a pressure controlled chamber. In the embodiment shown in FIG. 15, the process chamber 1510 is a spin chamber having a spinner 1520 (or spin chuck), which is configured to spin or rotate at a rotational speed. A substrate 1530 is held on the spinner 1520, for example, via electrostatic force or vacuum pressure. In one example, the substrate 1530 may be a semiconductor wafer having a transition metal nitride material, such as TiN, formed on or within the substrate 1530.

The processing system 1500 shown in FIG. 15 further includes a liquid nozzle 1540, which is positioned over the substrate 1530 for dispensing various etch solutions 1542 onto a surface of the substrate 1530. The etch solutions 1542 dispensed onto the surface of the substrate 1530 may generally include a surface modification solution to chemically modify the TiN surface and form a modified surface layer (e.g., a titanium oxide, titanium oxyhydroxide or titanium oxynitride passivation layer), and a dissolution solution to selectively remove the modified surface layer from the TiN surface. Purge solutions may also be dispensed onto the surface of the substrate 1530 between surface modification and dissolution steps to separate the surface modification and dissolution solutions. Examples of surface modification, dissolution and purge solutions are discussed above.

As shown in FIG. 15, the etch solutions 1542 may be stored within a chemical supply system 1546, which may include one or more reservoirs for holding the various etch solutions 1542 and a chemical injection manifold, which is fluidly coupled to the process chamber 1510 via a liquid supply line 1544. In operation, the chemical supply system 1546 may selectively apply desired chemicals to the process chamber 1510 via the liquid supply line 1544 and the liquid nozzle 1540 positioned within the process chamber 1510. Thus, the chemical supply system 1546 can be used to dispense the etch solutions 1542 onto the surface of the substrate 1530. The process chamber 1510 may further include a drain 1550 for removing the etch solutions 1542 from the process chamber 1510.

Components of the processing system 1500 can be coupled to, and controlled by, a controller 1560, which in turn, can be coupled to a corresponding memory storage unit and user interface (not shown). Various processing operations can be executed via the user interface, and various processing recipes and operations can be stored in the memory storage unit. Accordingly, a given substrate 1530 can be processed within the process chamber 1510 in accordance with a particular recipe. In some embodiments, a given substrate 1530 can be processed within the process chamber 1510 in accordance with an etch recipe that utilizes the wet ALE techniques described herein for etching TiN and other transition metal nitrides.

The controller 1560 shown in block diagram form in FIG. 15 can be implemented in a wide variety of manners. In one example, the controller 1560 may be a computer. In another example, the controller 1560 may include one or more programmable integrated circuits that are programmed to provide the functionality described herein. For example, one or more processors (e.g., microprocessor, microcontroller, central processing unit, etc.), programmable logic devices (e.g., complex programmable logic device (CPLD), field programmable gate array (FPGA), etc.), and/or other programmable integrated circuits can be programmed with software or other programming instructions to implement the functionality of a prescribed process recipe. It is further noted that the software or other programming instructions can be stored in one or more non-transitory computer-readable mediums (e.g., memory storage devices, flash memory, dynamic random access memory (DRAM) , reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

As shown in FIG. 15, the controller 1560 may be coupled to various components of the processing system 1500 to receive inputs from, and provide outputs to, the components. For example, the controller 1560 may be coupled to: the process chamber 1510 for controlling the temperature and/or pressure within the process chamber 1510; the spinner 1520 for controlling the rotational speed of the spinner 1520; and the chemical supply system 1546 for controlling the various etch solutions 1542 dispensed onto the substrate 1530. The controller 1560 may control other processing system components not shown in FIG. 15, as is known in the art.

In some embodiments, the controller 1560 may control the various components of the processing system 1500 in accordance with an etch recipe that utilizes the wet ALE techniques described herein for etching a titanium nitride (TiN) layer. For example, the controller 1560 may supply various control signals to the chemical supply system 1546, which cause the chemical supply system 1546 to: a) dispense a surface modification solution onto the surface of the substrate 1530 to chemically modify exposed surfaces of the TiN layer and create a chemically modified TiN surface layer (e.g., a titanium oxide, titanium oxyhydroxide or titanium oxynitride passivation layer) on the substrate 1530; b) rinse the substrate 1530 with a first purge solution to remove the surface modification solution and excess reactants from the surface; c) dispense a dissolution solution onto the surface of the substrate 1530 to selectively remove or dissolve the chemically modified TiN surface layer; and d) rinse the substrate with a second purge solution to remove the dissolution solution from the surface of the substrate 1530. In some embodiments, the controller 1560 may supply the control signals to the chemical supply system 1546 in a cyclic manner, such that the steps a)-d) are repeated for one or more ALE cycles, until a desired amount of the TiN layer has been removed.

The controller 1560 may also supply control signals to other processing system components. In some embodiments, for example, the controller 1560 may supply control signals to the spinner 1520 and/or the chemical supply system 1546 to dry the substrate 1530 after the second purge step is performed. In one example, the controller 1560 may control the rotational speed of the spinner 1520, so as to dry the substrate 1530 in a spin dry step. In another example, control signals supplied from the controller 1560 to the chemical supply system 1546 may cause a drying agent (such as, e.g., isopropyl alcohol) to be dispensed onto the surface of the substrate 1530 to further assist in drying the substrate before performing the spin dry step.

In some embodiments, the controller 1560 may control the temperature and/or the pressure within the process chamber 1510. In some embodiments, the surface modification, dissolution and purge steps of the wet ALE processes described herein may be performed at roughly the same temperature and pressure. In one example implementation, the surface modification, dissolution and purge steps may each be performed at (or near) atmospheric pressure and room temperature. Performing the processing steps within the same process chamber at roughly the same temperature and pressure decreases the cycle time and improves the throughput of the wet ALE process described herein by avoiding unnecessary chamber transitions and temperature/pressure changes.

It is noted, however, that the embodiments described herein are not strictly limited to only atmospheric pressure and room temperature, nor are they limited to a particular process chamber. In other embodiments, one or more of the surface modification, dissolution and purge steps can be run at above atmospheric pressure in a pressure vessel, or at reduced pressure in a vacuum chamber. Etch solutions can be dispensed in these environments as long as the vapor pressure of the liquid is lower than the chamber pressure. For these implementations, a spinner with a liquid dispensing nozzle would be placed in the pressure vessel or vacuum chamber. The temperature of the liquid being dispensed can be elevated to any temperature below its boiling point at the pressure of the process. In one example implementation, the surface modification and dissolution steps may be performed at an elevated temperature (for example, at about 50-60 °C) to increase the oxidation and dissolution rates and increase the TiN etch rate.

The present disclosure provides systems and methods that utilize new etch chemistries for etching titanium nitride (TiN) in a wet ALE process. As described above, the wet ALE processes and methods disclosed herein use a wide variety of techniques and etch chemistries to oxidize a TiN layer exposed on a surface of a substrate and form a self-limiting, titanium oxide, titanium oxyhydroxide or titanium oxynitride passivation layer in a surface modification step of the wet ALE process. After forming the titanium oxide, titanium oxyhydroxide or titanium oxynitride passivation layer, reactive dissolution in acidic solution is used in the dissolution step of the wet ALE process to provide self-limited, selective dissolution of the passivation layer without increasing the post-etch surface roughness. In some embodiments, the TiN etch rate is improved by increasing the temperature of and/or the exposure time to the surface modification and dissolution solutions, while preserving or even improving surface roughness.

Although described herein for etching titanium nitride (TiN), the techniques described herein may be used for etching other transition metal nitride materials such as, for example, molybdenum nitride (MoN), tantalum nitride (TaN), chromium nitride (CrN), gallium nitride (GaN), aluminum nitride (AlN), hafnium nitride (HfN), zirconium nitride (ZrN) and iron nitride (FeₓN). However, the techniques described herein may not be sufficient to modify surrounding dielectric surfaces, such as zirconium dioxide (ZrO₂), hafnium dioxide (HfO₂) or hafnium zirconium dioxide (HfₓZr₍₁₋ₓ₎O₂) dielectrics, due to the etch chemistry used during the surface modification step (e.g., APS) and/or the difficulty in changing the surface chemistry of such materials at or near room temperature. Thus, the etch chemistries and methods disclosed herein for etching TiN may provide good etch selectivity to such materials.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

1. A method of etching, the method comprising:
receiving a substrate having a titanium nitride (TiN) layer, wherein a TiN surface is exposed on a surface of the substrate;
exposing the surface of the substrate to a surface modification solution comprising an oxidizing agent dissolved in a first solvent, wherein the oxidizing agent reacts with the TiN surface to form a titanium oxide, titanium oxyhydroxide or titanium oxynitride passivation layer, which is self-limiting and insoluble in the surface modification solution;
removing the surface modification solution from the surface of the substrate subsequent to forming the titanium oxide, titanium oxyhydroxide or titanium oxynitride passivation layer;
exposing the surface of the substrate to a dissolution solution to selectively remove the titanium oxide, titanium oxyhydroxide or titanium oxynitride passivation layer and, wherein the dissolution solution reacts with the titanium oxide, titanium oxyhydroxide or titanium oxynitride passivation layer to form soluble species, which are dissolved by the dissolution solution to expose an unmodified TiN surface underlying the titanium oxide, titanium oxyhydroxide or titanium oxynitride passivation layer; and
removing the dissolution solution and the soluble species from the surface of the substrate to etch the TiN layer.

2. The method of claim 1, further comprising repeating said exposing the surface of the substrate to the surface modification solution, removing the surface modification solution, exposing the surface of the substrate to the dissolution solution, and removing the dissolution solution and the soluble species a number of times until a predetermined amount of the TiN layer is removed from the substrate.

3. The method of claim 1, wherein the substrate further comprises an oxide layer, wherein an oxide surface of the oxide layer is exposed on the surface of the substrate, and wherein the TiN layer is etched selective to the oxide layer.

4. The method of claim 3, wherein the oxide layer comprises hafnium dioxide (HfO₂), zirconium dioxide (ZrO₂) or hafnium zirconium dioxide (HfₓZr₍₁₋ₓ₎O₂).

5. The method of claim 1, wherein the oxidizing agent is ammonium persulphate (APS), hydrogen peroxide (H₂O₂), nitric acid (HNO₃), pyridine N-oxide (C₅H₅NO), 4-methyl morpholine (C₅H₁₁NO) or ozone (O₃), and wherein the first solvent is an aqueous solvent.

6. The method of claim 5, wherein the oxidizing agent is ammonium persulfate (APS) and the first solvent is deionized water.

7. The method of claim 5, wherein the surface modification solution comprises 1% to 20% ammonium persulfate (APS) dissolved in deionized water.

8. The method of claim 5, wherein said exposing the surface of the substrate to the surface modification solution comprises:
exposing the surface of the substrate to the surface modification solution at an elevated temperature ranging between 25 °C and 100 °C, wherein the elevated temperature increases an etch rate of the TiN layer by increasing an oxidation rate of the TiN surface.

9. The method of claim 1, wherein the dissolution solution comprises an acid, which reacts with the titanium oxide, titanium oxyhydroxide or titanium oxynitride passivation layer to form the soluble species, which are dissolved by the dissolution solution to expose the unmodified TiN surface underlying the titanium oxide, titanium oxyhydroxide or titanium oxynitride passivation layer.

10. The method of claim 9, wherein the acid is sulfuric acid (H₂SO₄), hydrochloric acid (HCl), hydrofluoric acid (HF) or another mineral acid.

11. The method of claim 9, wherein the dissolution solution comprises 0.05 mM to 5 M of sulfuric acid (H₂SO₄).

12. The method of claim 9, wherein said exposing the surface of the substrate to the dissolution solution comprises:
exposing the surface of the substrate to the dissolution solution at an elevated temperature ranging between 25 °C and 100 °C, wherein the elevated temperature increases an etch rate of the TiN layer by increasing a dissolution rate of the titanium oxide, titanium oxyhydroxide or titanium oxynitride passivation layer.

13. The method of claim 12, wherein the dissolution solution further comprises a ligand, which assists in the selective removal of the titanium oxide, titanium oxyhydroxide or titanium oxynitride passivation layer and/or increases the dissolution rate of the titanium oxide, titanium oxyhydroxide or titanium oxynitride passivation layer.

14. The method of claim 13, wherein the ligand is oxalic acid, formic acid, acetic acid, cupferron, ethylenediamine, ethylenediaminetetraacetic acid (EDTA), iminodiacetic acid, catechol, ascorbic acid, sodium ascorbate, calcium ascorbate or potassium ascorbate.

15. The method of claim 1, wherein the oxidizing agent is a non-peroxide oxidizer and the first solvent is an aqueous solvent or an organic solvent.

16. The method of claim 15, wherein the non-peroxide oxidizer comprises ammonium persulfate (APS), ferric chloride (FeCl₃), an osmium tetroxide, a ruthenium tetroxide, a ruthenate, a manganate, a permanganate, a periodate, or a metal nitrate.

17. The method of claim 1, wherein the oxidizing agent comprises a peroxide oxidizer and the first solvent is an organic solvent.

18. The method of claim 17, wherein the peroxide oxidizer comprises hydrogen peroxide (H₂O₂), a symmetric organic peroxide, an asymmetric organic peroxide, a monoperoxide, or a peroxy acid.

19. A method of etching a substrate using a wet atomic layer etching (ALE) process, the method comprising:
receiving the substrate, the substrate having a titanium nitride (TiN) layer, wherein a TiN surface is exposed on a surface of the substrate; and
selectively etching the TiN layer by performing multiple cycles of the wet ALE process, wherein each cycle comprises:
exposing the TiN surface to a first etch solution comprising an oxidizing agent dissolved in an aqueous solvent to form a chemically modified TiN surface layer that is self-limiting and insoluble in the first etch solution;
rinsing the substrate with a first purge solution to remove the first etch solution from the surface of the substrate;
exposing the chemically modified TiN surface layer to a second etch solution to selectively dissolve the chemically modified TiN surface layer and expose an unmodified TiN surface underlying the chemically modified TiN surface layer; and
rinsing the substrate with a second purge solution to remove the second etch solution from the surface of the substrate and etch the TiN layer.

20. The method of claim 19, wherein the oxidizing agent reacts with the TiN surface to form a titanium oxide, titanium oxyhydroxide or titanium oxynitride passivation layer, which is self-limiting and insoluble in the first etch solution.

21. The method of claim 20, wherein the first etch solution comprises ammonium persulfate (APS) dissolved in deionized water, and wherein a concentration of the APS in the first etch solution ranges between 1% and 20%.

22. The method of claim 20, wherein the second etch solution comprises an acid, wherein the titanium oxide, titanium oxyhydroxide or titanium oxynitride passivation layer is selectively dissolved by the acid to expose the unmodified TiN surface underlying the titanium oxide, titanium oxyhydroxide or titanium oxynitride passivation layer.

23. The method of claim 22, wherein the second etch solution comprises 0.05 mM to 5 M of sulfuric acid (H₂SO₄).

24. The method of claim 19, wherein the substrate further comprises an oxide layer, wherein an oxide surface of the oxide layer is exposed on the surface of the substrate, and wherein said selectively etching the TiN layer is selective to the oxide layer.

25. The method of claim 24, wherein the oxide layer comprises hafnium dioxide (HfO₂), zirconium dioxide (ZrO₂) or hafnium zirconium dioxide (HfₓZr₍₁₋ₓ₎O₂).
